(19) United States
(12) Patent Application Publication
(10) Pub. No.: US 2025/0133728 A1
(43) Pub. Date: Apr. 24, 2025

(54) SEMICONDUCTOR DEVICE

(71) Applicant: SAMSUNG ELECTRONICS CO., LTD., Suwon-si (KR)

(72) Inventors: Iljae Shin, Suwon-si (KR); Jinwoo Han, Suwon-si (KR); Seokhan Park, Suwon-si (KR); Sungmin Park, Suwon-si (KR); Gyuhwan Oh, Suwon-si (KR); Kiseok Lee, Suwon-si (KR)

(21) Appl. No.: 18/825,982

(22) Filed: Sep. 5, 2024

(30) Foreign Application Priority Data
Oct. 24, 2023 (KR) 10-2023-0142597

(51) Int. Cl. H10B 12/00; H01L 29/45

(52) U.S. Cl. CPC H10B 12/482; H10B 12/485; H10B 12/488; H10D 64/62

(57) ABSTRACT

A semiconductor device includes a bit line, a channel, a word line and a capacitor. The bit line is disposed on a substrate, and extends in a first direction substantially perpendicular to an upper surface of the substrate. The channel at least partially surrounds a sidewall of the bit line. The word line is disposed on the substrate, and at least a portion of the word line overlaps the channel in a horizontal direction substantially parallel to the upper surface of the substrate. The capacitor is electrically connected to the channel, and at least a portion of the capacitor overlaps the channel and the word line in the horizontal direction.

### CROSS-REFERENCE TO RELATED APPLICATION

This application claims priority to Korean Patent Application No. 10-2023-0142597, filed in the Korean Intellectual Property Office on Oct. 24, 2023, the disclosure of which is incorporated by reference herein in its entirety.

### BACKGROUND

A DRAM device includes word lines, bit lines, channels and capacitors. In order to increase the integration degree of the DRAM device, the word lines, the bit lines, the channels and the capacitors are needed to be efficiently arranged.

### SUMMARY

In general, in some aspects, the present disclosure is directed toward a semiconductor device that includes memory cells having a reduced vertical thickness and height to increase an integration degree and enhanced electric characteristics.

According to some implementations, the present disclosure is directed to a semiconductor device that includes a bit line, a channel, a word line and a capacitor. The bit line may be disposed on a substrate, and may extend in a first direction substantially perpendicular to an upper surface of the substrate. The channel may at least partially surround a sidewall of the bit line. The word line may be disposed on the substrate, and at least a portion of the word line may overlap the channel in a horizontal direction substantially parallel to the upper surface of the substrate. The capacitor may be electrically connected to the channel, and at least a portion of the capacitor may overlap the channel and the word line in the horizontal direction.

According to some implementations, the present disclosure is directed to a semiconductor device that includes a bit line, a back gate electrode, a channel, a word line and a capacitor. The bit line may be disposed on a substrate, and may extend in a first direction substantially perpendicular to an upper surface of the substrate. The back gate electrode may extend in the first direction on the substrate, and may be spaced apart from the bit line in a horizontal direction substantially parallel to the upper surface of the substrate. The channel may surround a sidewall of the back gate electrode, and may be electrically connected to the bit line. The word line may be disposed on the substrate, and at least a portion of the word line may overlap the channel in the horizontal direction. The capacitor may be electrically connected to the channel, and at least a portion of the capacitor may overlap the channel and the word line in the horizontal direction.

According to some implementations, the present disclosure is directed to a semiconductor device that includes bit lines, channels, word lines, capacitors and contact plugs. The bit lines may be disposed on a substrate, and each of the bit lines may extend in a first direction substantially perpendicular to an upper surface of the substrate. The bit lines may be spaced apart from each other in a second direction substantially parallel to the upper surface of the substrate. The channels may be spaced apart from each other in the first direction on a sidewall of each of the bit lines, and each of the channels may at least partially surround the sidewall of each of the bit lines. The word lines may be spaced apart from each other in the first direction on the substrate, and each of the word lines may extend in the second direction. At least a portion of each of the word lines may overlap a corresponding one of the channels in the second direction. The capacitors may be spaced apart from each other in the first direction, and at least a portion of each of the capacitors may overlap a corresponding one of the channels in a third direction substantially parallel to the upper surface of the substrate and intersecting the second direction. The contact plugs may contact upper surfaces of corresponding ones, respectively, of the word lines, and each of the contact plugs may extend in the first direction.

In some implementations, the present disclosure is directed to a semiconductor device, in which the channel and the capacitor are disposed at the same level as each of the word lines, and each of the memory cells including the channel and the capacitor may have a reduced vertical thickness.

### BRIEF DESCRIPTION OF THE DRAWINGS

Example implementations will be more clearly understood from the following detailed description, taken in conjunction with the accompanying drawings.

FIGS. 1 to 3 are a plan view and cross-sectional views illustrating an example of a semiconductor device in accordance with some implementations.

FIGS. 4 to 31 are plan views and cross-sectional views illustrating an example of a method of manufacturing a semiconductor device in accordance with some implementations.

FIG. 32 is a cross-sectional view illustrating an example of a semiconductor device in accordance with some implementations.

FIGS. 33 and 34 are a plan view and a cross-sectional view illustrating an example of a semiconductor device in accordance with some implementations.

FIGS. 35 and 36 are a plan view and a cross-sectional view illustrating an example of a semiconductor device in accordance with some implementations.

FIGS. 37 to 48 are plan views and cross-sectional views illustrating an example of a method of manufacturing a semiconductor device in accordance with some implementations.

FIGS. 49 to 51 are a plan view and cross-sectional views illustrating an example of a semiconductor device in accordance with some implementations.

FIGS. 52 to 66 are plan views and cross-sectional views illustrating an example of a method of manufacturing a semiconductor device in accordance with some implementations.

FIG. 67 is a plan view illustrating an example of a semiconductor device in accordance with some implementations.

FIGS. 68 to 70 are plan views illustrating an example of a method of manufacturing a semiconductor device in accordance with some implementations.

### DETAILED DESCRIPTION

Hereinafter, example implementations will be explained in detail with reference to the accompanying drawings. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Accordingly, “first”, “second” and/or “third” may be used selectively or interchangeably for each material, layer, region, electrode, pad, pattern, structure or process respectively.

A direction substantially vertical to an upper surface of a substrate may be referred to as a first direction D1, and two directions among horizontal directions that are substantially parallel to the upper surface of the substrate, which intersect each other, may be referred to as second and third directions D2 and D3, respectively. In some implementations, the second and third directions D2 and D3 may be substantially perpendicular to each other.

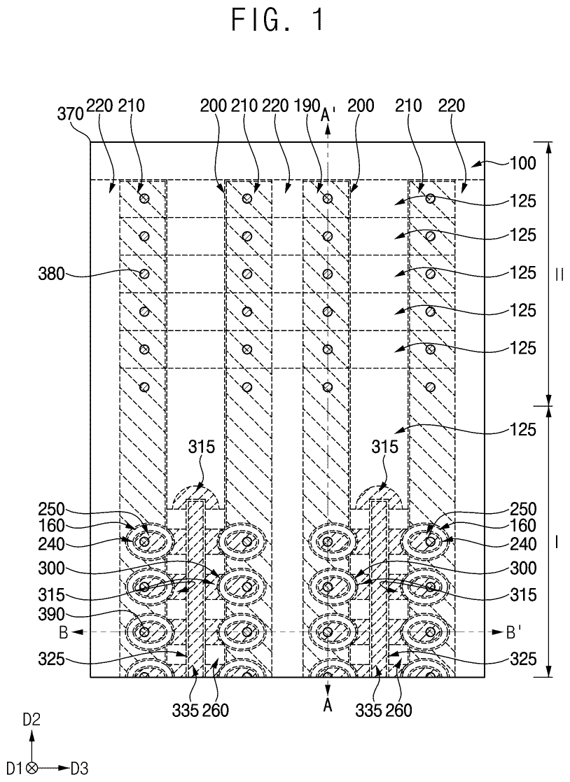

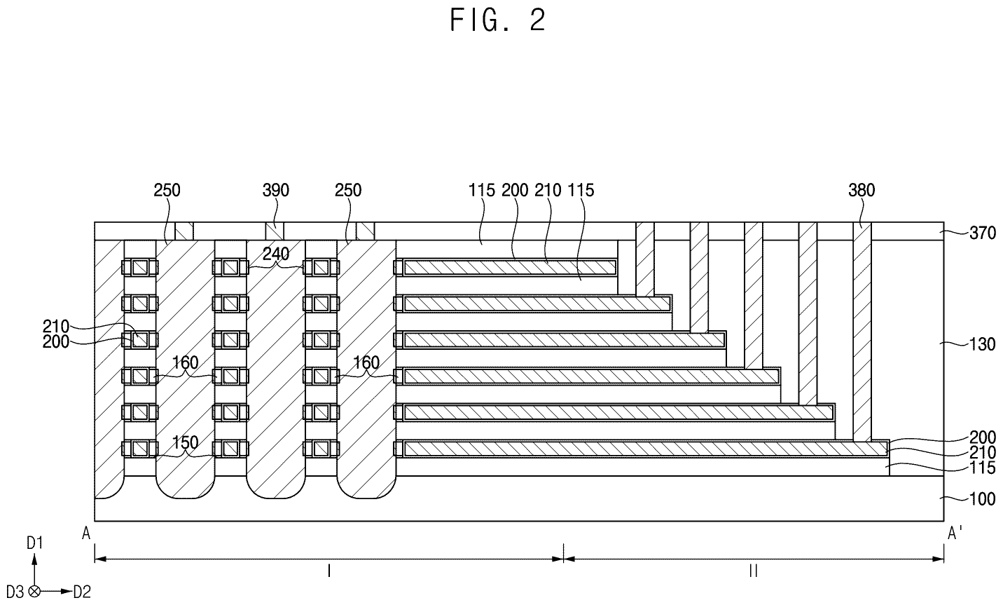

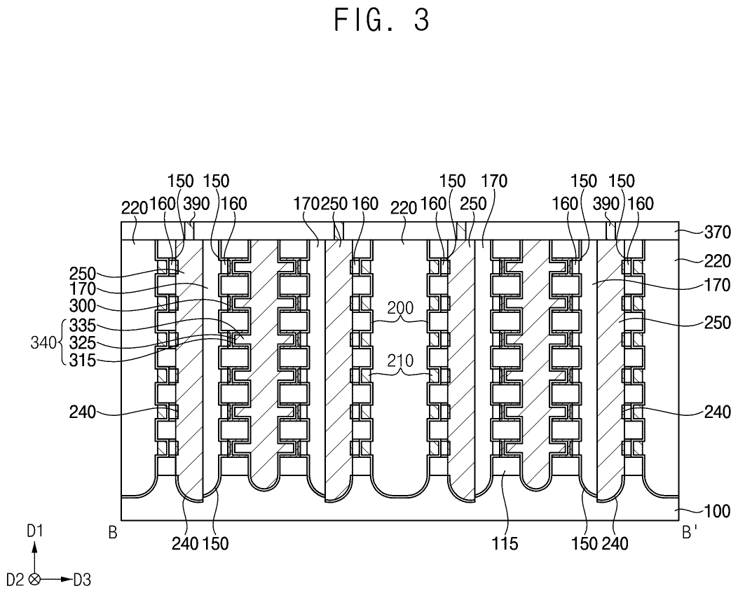

FIGS. 1 to 3 are a plan view and cross-sectional views illustrating an example of a semiconductor device in accordance with some implementations. FIG. 1 is the plan view, FIG. 2 is a cross-sectional view taken along line A-A′ of FIG. 1, and FIG. 3 is a cross-sectional view taken along line B-B′ of FIG. 1.

In FIGS. 1 to 3, a semiconductor device may include a first gate electrode 210, a first gate insulation layer 200, a bit line 250, a channel 160, first and second ohmic contact patterns 240 and 300, a capacitor structure 340, and first and second contact plugs 380 and 390 on a substrate 100.

The semiconductor device may further include first, third, fourth, and fifth insulation patterns 115, 170, 220, and 260, a second insulation layer 150, a first insulating interlayer 130, and a second insulating interlayer 370.

The substrate 100 may include a semiconductor material, e.g., silicon, germanium, silicon-germanium, etc., or a III-V group compound semiconductor, such as GaP, GaAs, GaSb, etc. In some implementations, the substrate 100 may be a silicon-on-insulator (SOI) substrate or a germanium-on-insulator (GOI) substrate.

The substrate 100 may include a first region I and a second region II. The first region I may be a cell region on which memory cells are formed, and the second region II may be an extension region or a pad region on which contact plugs for transferring electrical signals to the memory cells are formed. In some implementations, the second region II may surround the first region I. In some implementations, the second region II may be disposed at opposite sides of the first region I in the second direction D2.

The first gate electrode 210 may extend in the second direction D2 on the first region I and the second region II of the substrate 100, and a plurality of first gate electrodes 210 may be spaced apart from each other in the first direction D1 to form a first gate electrode structure. The first insulation pattern 115 may be disposed between neighboring ones of the first gate electrodes 210 in the first direction D1, and the first insulation pattern 115 may also be disposed between the substrate 100 and a lowermost one of the first gate electrodes 210 and on an uppermost one of the first gate electrodes 210. Each of the first gate electrodes 210 may serve as a word line of the semiconductor device, and the first gate electrode structure may also be referred to as a word line structure.

In some implementations, extension lengths in the second direction D2 of the first gate electrodes 210 may decrease from a lowermost level to an uppermost level in a stepwise manner, and the first gate electrode structure may have a staircase shape. A portion of each of the first gate electrodes 210 not overlapped by ones of the first gate electrodes 210 over each of the first gate electrodes 210, that is, an end portion in the second direction D2 of each of the first gate electrodes 210 may be referred as a pad. In some implementations, the pads may be disposed in the second direction D2 on the second region II of the substrate 100. The first gate electrode 210 may include, e.g., a metal, a metal nitride, a metal silicide, doped polysilicon, etc.

In some implementations, a plurality of first gate electrode structures may be spaced apart from each other in the third direction D3, and the fourth insulation pattern 220 and the first sacrificial pattern 125 may be alternately and repeatedly disposed in the third direction D3 between the first gate structures. The fourth insulation pattern 220 may extend in the second direction D2 on the first region I and the second region II of the substrate 100 through the first gate electrode structure and the first insulation patterns 115. The first sacrificial pattern 125 and the first insulation pattern 115 may be alternately and repeatedly stacked in the first direction D1, and may extend through the first gate electrode structure between ones of the fourth insulation patterns 220 neighboring in the third direction D3 to divide the first gate electrode structure into two parts in the third direction D3.

Each of the first insulation pattern 115 and the fourth insulation pattern 220 may include an oxide, e.g., silicon oxide, and the first sacrificial pattern 125 may include a material having an etching selectivity with respect to the first insulation pattern 115, e.g., an insulating nitride such as silicon nitride.

The first gate insulation layer 200 may cover upper and lower surfaces of the first gate electrode 210, a sidewall facing the first sacrificial pattern 125, and a sidewall facing the channel 160 of the first gate electrode 210, and may also be formed on a sidewall of the first insulation pattern 115 facing the fourth insulation pattern 220. The first gate insulation layer 200 may include an oxide, e.g., silicon oxide.

The bit line 250 may be disposed on the first region I of the substrate 100, and may have a shape of a pillar extending in the first direction D1. The bit line 250 may extend through the first gate electrode structure and the first insulation patterns 115. In some implementations, a plurality of bit lines 250 may extend through the first gate electrode structure extending in the second direction D2, and may be spaced apart from each other in the second direction D2. Accordingly, a plurality of bit lines 250 may be spaced apart from each other in the second direction D2 and the third direction D3. The bit line 250 may include, e.g., a metal, a metal nitride, a metal silicide, doped polysilicon, etc.

The third insulation pattern 170 may be disposed on the first region I of the substrate 100, and may have a pillar shape extending through the first gate electrode structure and the first insulation patterns 115. In some implementations, the third insulation pattern 170 may contact a sidewall of the bit line 250 in the third direction D3, and the third insulation pattern 170 together with the bit line 250 may have a shape of, e.g., a circle, an ellipse, a polygon, a polygon with rounded corners, etc., in a plan view. Each of the bit line 250 and the third insulation pattern 170 may extend through an upper portion of the substrate 100, and in some implementations, a lowermost surface of the bit line 250 may be lower than a lowermost surface of the third insulation pattern 170. The third insulation pattern 170 may include an oxide, e.g., silicon oxide.

The channel 160 may be disposed at a level where each of the first gate electrodes 210 is disposed, and may surround sidewalls of the bit line 250 and the third insulation pattern 170. The channel 160 may contact the sidewall of the third insulation pattern 170, and the first ohmic contact pattern 240 may be disposed between the channel 160 and the bit line 250. The first gate insulation layer 200 may be disposed between the channel 160 and the first gate electrode 210.

Lower and upper surfaces of the channel 160 may be covered by the second insulation layer 150, and the second insulation layer 150 may contact a sidewall of a portion of the first insulation pattern 115 between neighboring ones of the channels 160 in the first direction D1 and a sidewall of a portion of the third insulation pattern 170 opposite thereto. Additionally, the second insulation layer 150 may cover a lower surface of the third insulation pattern 170, and may also contact the upper surface of the substrate 100. The second insulation layer 150 may include an oxide, e.g., silicon oxide, and in some cases, may be merged with the first insulation pattern 115 and/or the third insulation pattern 170.

In some implementations, the channel 160 may have a shape of a circular ring, an elliptical ring, a polygonal ring, etc. The channel 160 may be disposed at each level where the first gate electrode 210 is disposed, and a plurality of channels 160 may be disposed in the first direction D1. The channel 160 may surround the sidewalls of the bit line 250 and the third insulation pattern 170, and a plurality of channels 160 may be spaced apart from each other in the second and third directions D2 and D3.

The channel 160 may include a semiconductor material, e.g., silicon, germanium, silicon-germanium, etc., or an oxide semiconductor material. The oxide semiconductor material may include at least one of zinc tin oxide (ZTO), indium zinc oxide (IZO), zinc oxide (ZnOₓ), indium gallium zinc oxide (IGZO), indium gallium silicon oxide (IGSO), Indium oxide (InOₓ, In₂O₃), tin oxide (SnO₂), titanium oxide (TiOₓ), zinc oxide nitride (ZnₓOyN_{z}), magnesium zinc oxide (MgₓZn_{y}O₂), indium zinc oxide (InₓZn_{y}Oₐ), indium gallium zinc oxide (InₓGa_{y}Zn_{z}Oₐ), zirconium indium zinc oxide (ZrₓIn_{y}Zn_{z}Oₐ), hafnium indium zinc oxide (HfₓIn_{y}Zn_{z}Oₐ), tin indium zinc oxide (SnₓIn_{y}Zn_{z}Oₐ), aluminum tin indium zinc oxide (AlₓSn_{y}In_{z}ZnₐO_{d}), silicon indium zinc oxide (SiₓIn_{y}Zn_{z}Oₐ), zinc tin oxide (ZnₓSn_{y}O_{z}), aluminum zine tin oxide (AlₓZn_{y}Sn_{z}Oₐ), gallium zinc tin oxide (GaₓZn_{y}Sn_{z}Oₐ), zirconium zinc tin oxide (ZrₓZn_{y}Sn_{z}Oₐ) and indium gallium silicon oxide (InGaSiO).

The first ohmic contact pattern 240 may cover a lower surface of the bit line 250, and may also contact the upper surface of the substrate 100. The first ohmic contact pattern 240 may include a metal silicide, e.g., cobalt silicide, nickel silicide, titanium silicide, etc.

In some implementations, the first ohmic contact pattern 240 may not be formed between the channel 160 and the sidewall of the bit line 250, and in this case, for example, n-type impurity region or a p-type impurity region may be formed at a lateral portion of the channel 160 facing the sidewall of the bit line 250 so as to serve as the first ohmic contact pattern 240.

The capacitor structure 340 may include a first capacitor electrode 315, a dielectric pattern 325, and a second capacitor electrode 335 sequentially stacked. The second capacitor electrode 335 may include an extension portion extending through the first insulation patterns 115 in the first direction D1 and the second direction D2 and a first protrusion portion protruding in the third direction D3 from each of opposite sidewalls in the third direction D3 of the extension portion on the first region I of the substrate 100. In some implementations, the second capacitor electrode 335 may include a plurality of first protrusion portions facing sidewalls in the third direction D3 of corresponding ones, respectively, of the channels 160. Accordingly, the second capacitor electrode 335 may include a plurality of first protrusion portions spaced apart from each other in the first direction D1 and the second direction D2 on each of opposite sidewalls in the third direction D3.

The second capacitor electrode 335 may further include a second protrusion portion protruding from each of end portions in the second direction D2 of the extension portion and having a shape of a semi-circle in a plan view. A plurality of second protrusion portions may be spaced apart from each other in the first direction D1, and the second protrusion portions may be disposed at respective levels where the channels are disposed.

The dielectric pattern 325 may cover a sidewall and a lower surface of the second capacitor electrode 335. The dielectric pattern 325 may cover lower and upper surfaces, opposite sidewalls in the second direction D2, and a sidewall in the third direction D3 of each of the first protrusion portions of the second capacitor electrode 335.

The first capacitor electrode 315 may cover lower and upper surfaces and a sidewall of a portion of the dielectric pattern 325 covering the lower and upper surfaces and the sidewalls of the first protrusion portion of the second capacitor electrode 335. A plurality of first capacitor electrodes 315 may be spaced apart from each other in the second direction D2 and the third direction D3 correspondingly to the channels 160, and may also be spaced apart from each other in the first direction D1. Each of the first capacitor electrodes 315 may be disposed at a level where a corresponding one of the channels 160 is disposed.

In the capacitor structure 340, each of the first capacitor electrodes 315, a portion of the dielectric pattern 325 that is disposed at the same level as each of the first capacitor electrodes 315, and a portion of the second capacitor electrode 335 at the same level as the portion of the dielectric pattern 325 may collectively form a capacitor. Accordingly, the capacitor structure 340 may include a plurality of capacitors spaced apart from each other in the second direction D2 and the third direction D3 correspondingly to the layout of the first capacitor electrodes 315, and a plurality of capacitors may also be disposed at a plurality of levels, respectively, in the first direction D1.

In some implementations, an outer sidewall in the third direction D3 of the first capacitor electrode 315 of each of the capacitors may contact the second ohmic contact pattern 300, and may be electrically connected to the channel 160 through the second ohmic contact pattern 300. The outer sidewall in the third direction D3 of the first capacitor electrode 315 of each of the capacitors may face the sidewall of the bit line 250 at least partially covered by the channel 160. Additionally, an outer sidewall in the second direction D2 of the first capacitor electrode 315 may contact the fifth insulation pattern 260.

The first capacitor electrode 315 may also be formed on lower and upper surfaces and a sidewall of a portion of the dielectric pattern 325 covering lower and upper surfaces and a sidewall of the second protrusion portion of the second capacitor electrode 335.

The fifth insulation pattern 260 may extend in the first direction D1 through the first insulation patterns 115 on the first region I of the substrate 100, and may be disposed between neighboring ones of the first capacitor electrodes 315 in the second direction D2 at each of opposite sides of the second capacitor 335 in the third direction D3. That is, the neighboring ones of the first capacitor electrodes 315 in the second direction D2 may be spaced apart from each other by the fifth insulation pattern 260 to be electrically insulated from each other. Accordingly, a plurality of fifth insulation patterns 260 may be spaced apart from each other in the second direction D2 at each of opposite sides of the second capacitor electrode 335 in the third direction D3.

The fifth insulation pattern 260 may also contact a sidewall of the first gate insulation layer 200. The fifth insulation pattern 260 may include an oxide, e.g., silicon oxide, or an insulating nitride, e.g., silicon nitride.

Each of the first capacitor 315 and the second capacitor 335 may include, e.g., a metal, a metal nitride, a metal silicide, doped polysilicon, etc., and the dielectric pattern 320 may include a metal oxide having a high dielectric constant, e.g., hafnium oxide, zirconium oxide, etc.

The first insulating interlayer 130 and the second insulating interlayer 370 may be sequentially stacked in the first direction D1 on the substrate 100, the first insulating interlayer 130 may cover sidewalls of the first gate electrode structure and the first insulation patterns 115, and the second insulating interlayer 370 may be disposed on the first insulating interlayer 130, the first gate electrode structure, the bit line 250, the capacitor structure 340, the third to fifth insulation patterns 170, 220, and 260, and the second insulation layer 150. Each of the first insulating interlayer 130 and the second insulating interlayer 370 may include an oxide, e.g., silicon oxide.

The first contact plug 380 may extend through the first insulating interlayer 130 and the second insulating interlayer 370 and the first gate insulation layer 200 to contact an upper surface of a pad of each of the first gate electrodes 200 on the first region I of the substrate 100, and the second contact plug 390 may extend through the second insulating interlayer 370 to contact an upper surface of the bit line 250 on the first region I of the substrate 100.

A third contact plug extending through the second insulating interlayer 370 to contact an upper surface of the second capacitor electrode 335 may be further formed. Each of the first contact plug 380, the second contact plug 390, and the third contact plug may include a metal, a metal nitride, a metal silicide, doped polysilicon, etc.

As illustrated above, in the semiconductor device, the channel 160 and the first capacitor electrode 315 may be disposed at the same level as each of the first gate electrodes 210, and, when compared to a case in which the first gate electrode 210 is disposed over and/or under the channel 160 and the first capacitor electrode 315, a thickness in the first direction D1, that is, in the vertical direction of a memory cell including the first gate electrode 210, the channel 160 and the capacitor electrode 315 may be reduced. Accordingly, a vertical thickness and a height of the upper surface of the semiconductor device may be reduced.

The channel 160 may surround the sidewalls of the bit line 250 and the third insulation pattern 170, and the first capacitor electrodes 315, the channels 160, and the bit lines 250 at opposite sides, respectively, in the third direction D3 may be symmetrical with reference to the extension portion of the second capacitor 335 extending in the second direction D2. Additionally, the bit line 250, the first capacitor electrode 315, and a portion of the channel 160 therebetween may be disposed in the third direction D3 that is perpendicular to the extension direction of the first gate electrode 210.

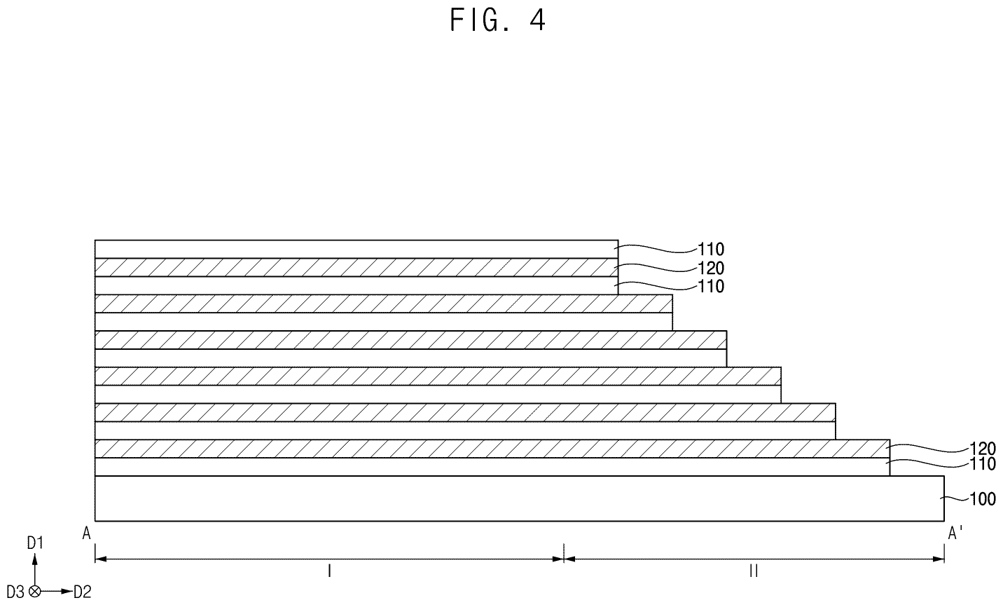

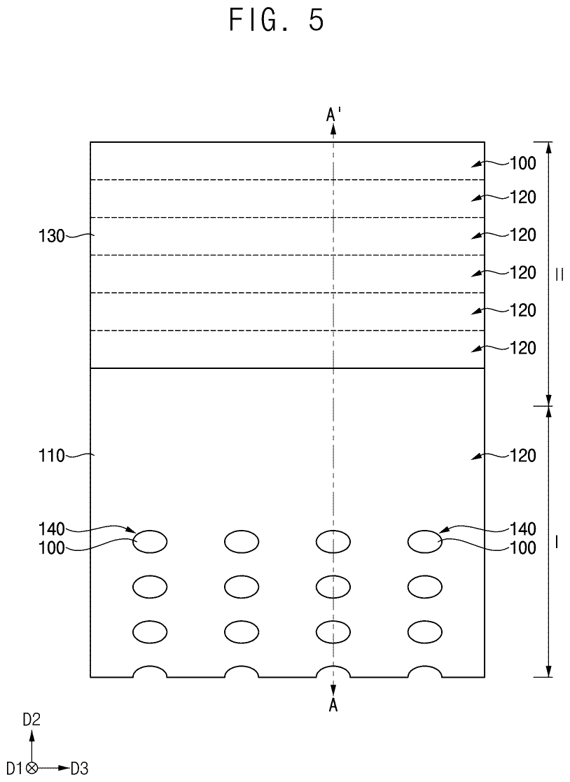

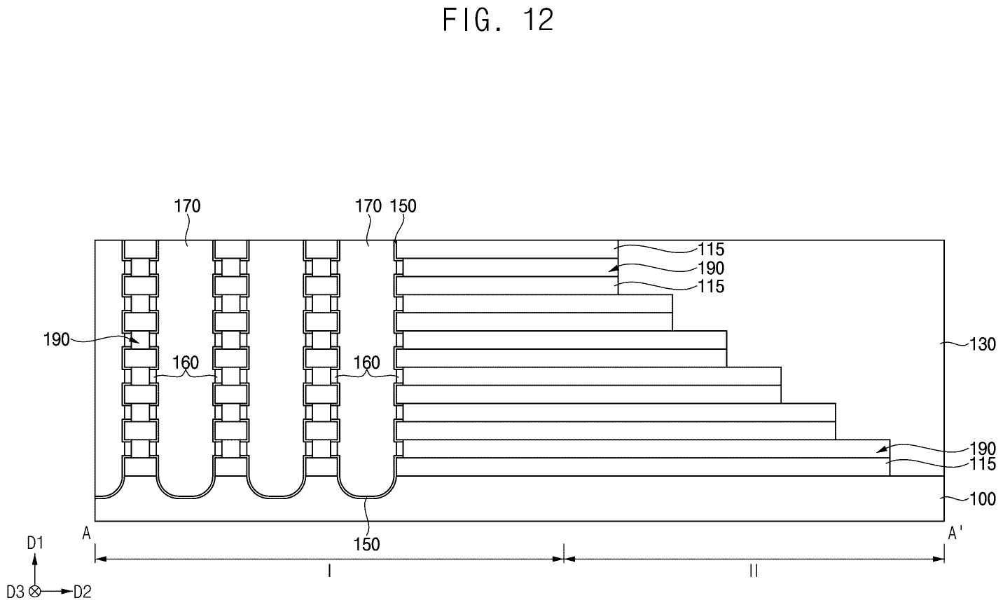

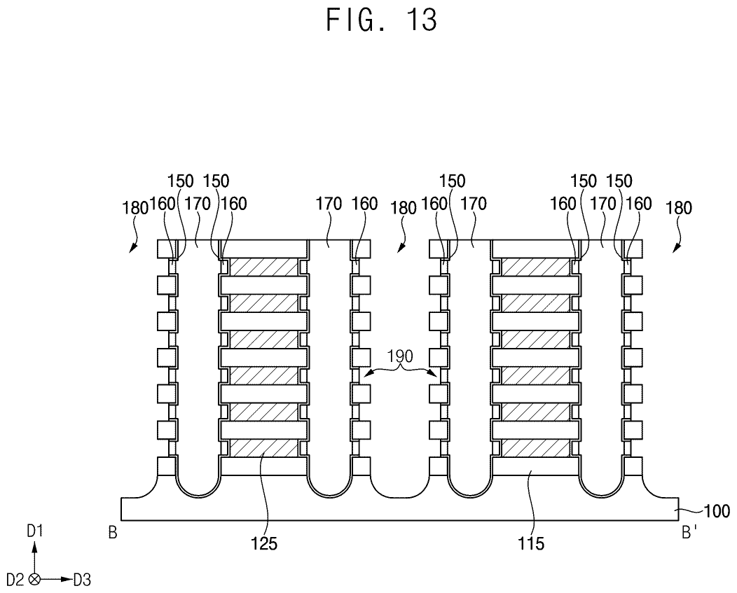

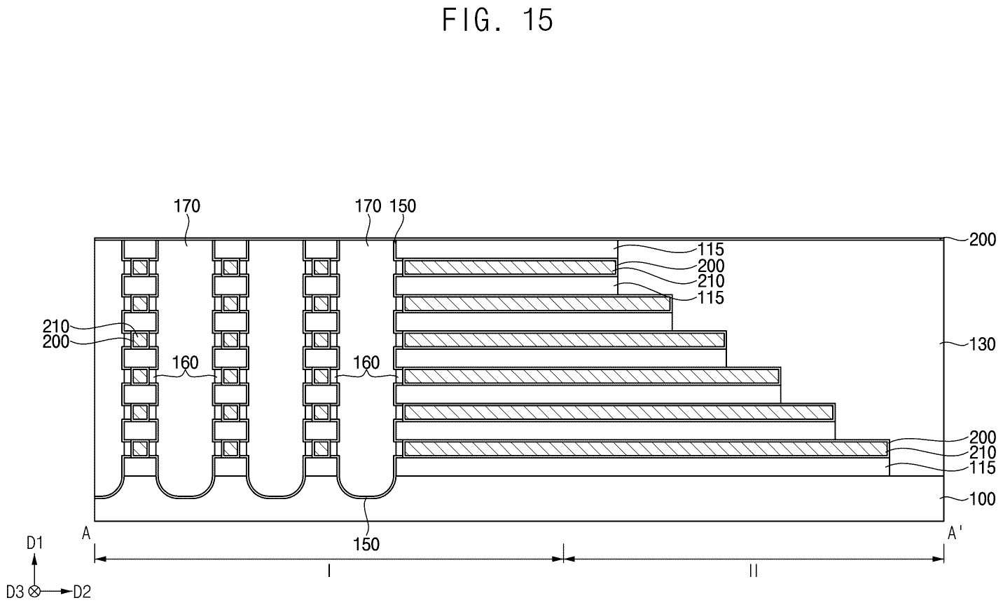

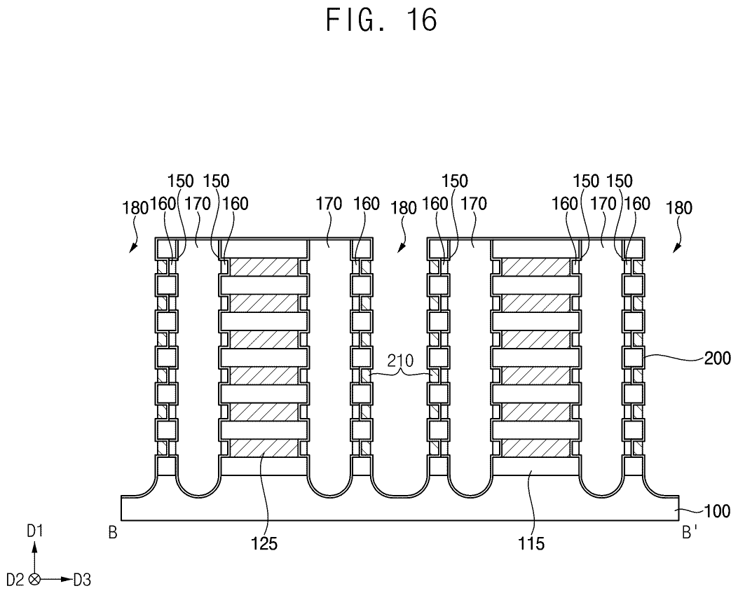

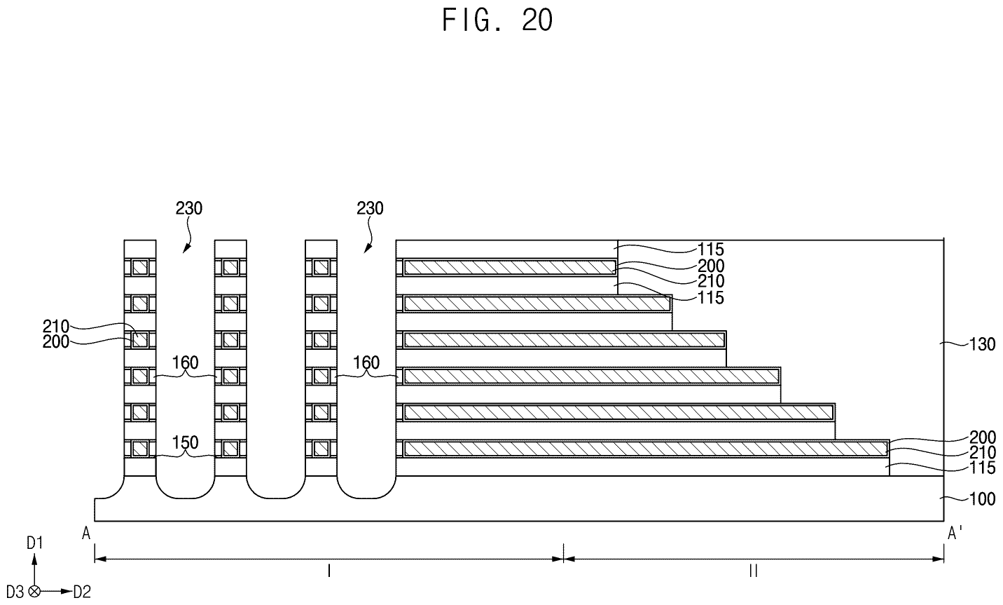

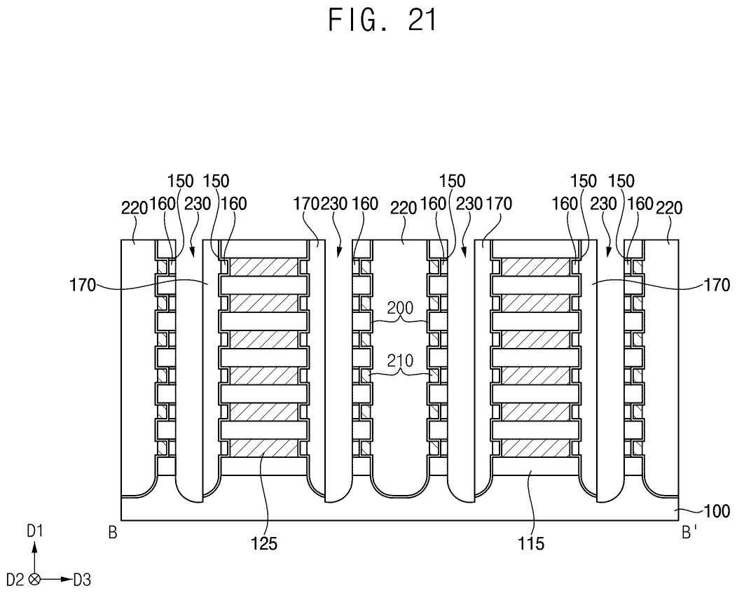

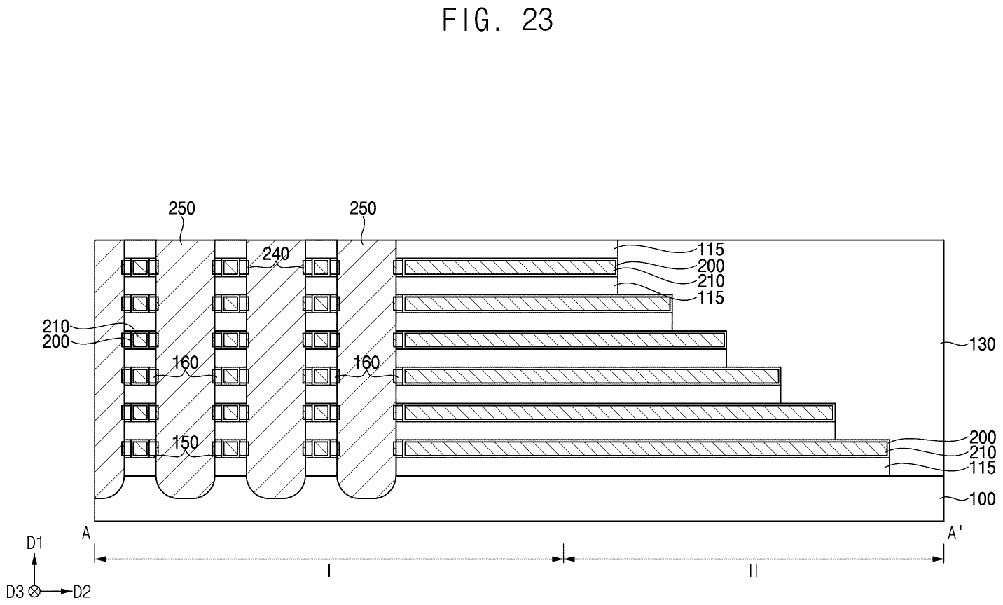

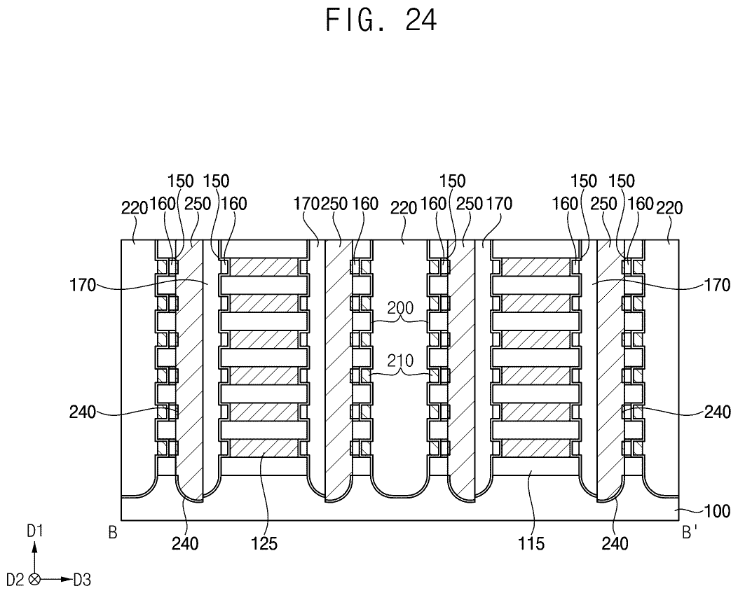

FIGS. 4 to 31 are plan views and cross-sectional views illustrating an example of a method of manufacturing a semiconductor device in accordance with some implementations. Particularly, FIGS. 5, 9, 11, 14, 19, 22, 25-26, 28 and 30 are the plan views, FIGS. 4, 6-8, 10, 12, 15, 17, 20 and 23 are cross-sectional views taken along lines A-A′ of corresponding plan views, respectively, and FIGS. 13, 16, 18, 21, 24, 27, 29 and 31 are cross-sectional views taken along lines B-B′ of corresponding plan views, respectively.

In FIG. 4, a first insulation layer 110 and a first sacrificial layer 120 may be alternately and repeatedly stacked on a substrate 100 including a first region I and a second region II to form a mold layer, a photoresist pattern may be formed on the mold layer, and an etching process using the photoresist pattern as an etching mask and a trimming process on the photoresist pattern may be alternately and repeatedly performed to form a mold having a staircase shape.

The first insulation layer 110 may include an oxide, e.g., silicon oxide, and the first sacrificial layer 120 may include a material having an etching selectivity with respect to the first insulation layer 110, e.g., an insulating nitride such as silicon nitride.

The mold may include step layers each of which may include the first insulation layer 110 and the first sacrificial layer 120 stacked in the first direction D1, and lengths in the second direction D2 of the step layers may decrease from a lowermost level to an uppermost level in a stepwise manner. Hereinafter, a portion of each of the step layers that is not overlapped by upper step layers in the first direction D1, that is, an end portion in the second direction D2 of each of the step layers may be referred to as a step.

In some implementations, the steps of the mold may be formed on the second region II of the substrate 100. FIG. 4 shows that each step layer includes the first insulation layer 110 and the first sacrificial layer 120 sequentially stacked in the first direction D1 in this order, however, the present disclosure is not limited thereto, and for example, each step layer may include the first sacrificial layer 120 and the first insulation layer 110 sequentially stacked in the first direction D1 in this order.

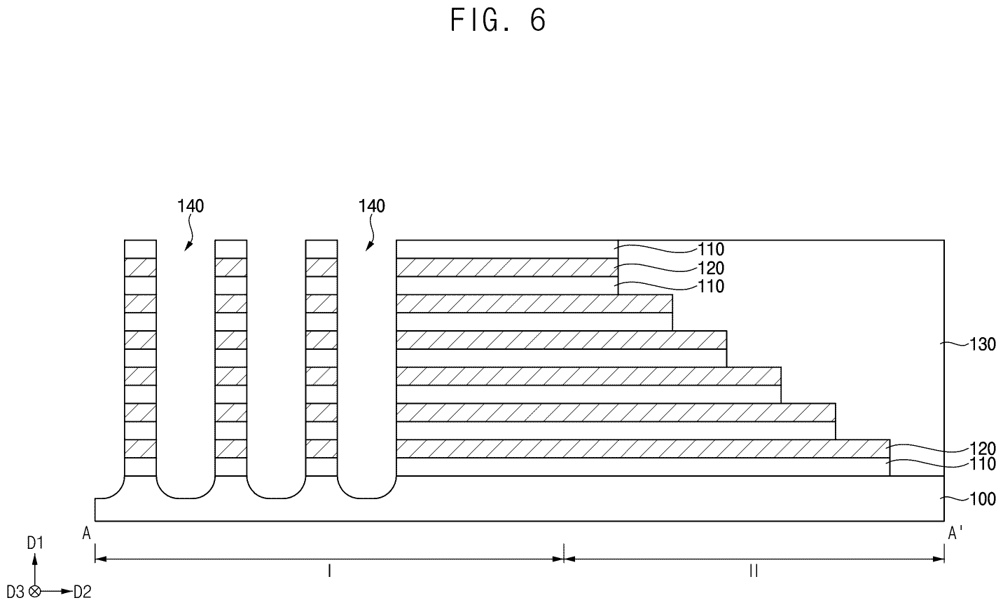

In FIGS. 5 and 6, a first insulating interlayer 130 may be formed on the substrate 100 to cover the mold, and a planarization process may be performed on the first insulating interlayer 130 until an upper surface of the mold is exposed, and the first insulating interlayer 130 may cover a sidewall of the mold. The planarization process may include, e.g., a chemical mechanical polishing (CMP) process and/or an etch back process.

An etching process may be performed on a portion of the mold on the first region I of the substrate 100 to form a first hole 140 extending in the first direction D1 and exposing an upper surface of the substrate 100. The first hole 140 may also extend through an upper portion of the substrate 100, and a plurality of first holes 140 may be spaced apart from each other in the second direction D2 and the third direction D3. Each of the first holes 140 may have a shape of, e.g., a circle, an ellipse, a polygon, a polygon with rounded corners, etc.

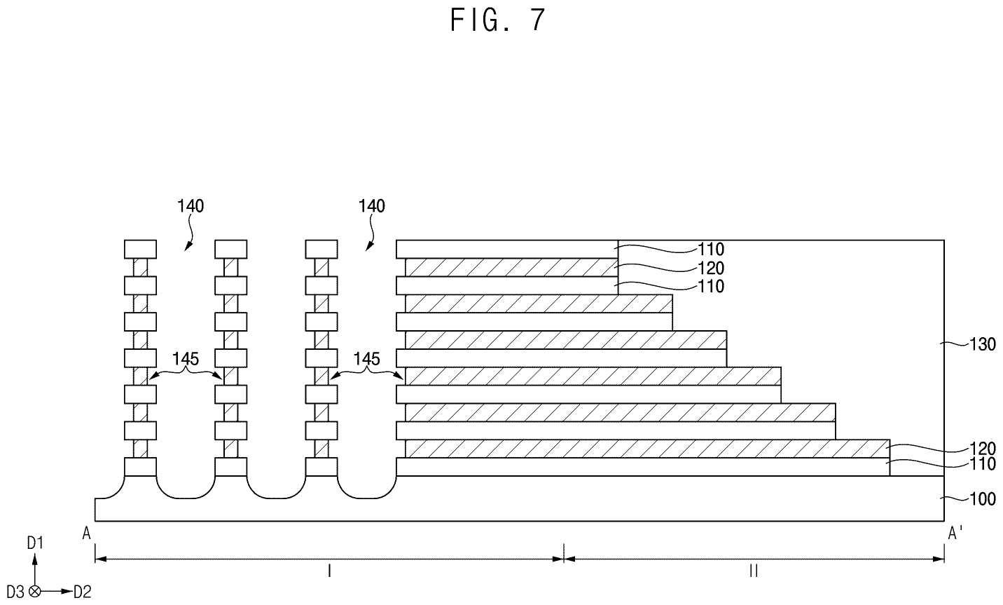

In FIG. 7, a lateral portion of the first sacrificial layer 120 exposed by the first hole 140 may be removed to form a first recess 145. In some implementations, the first recess 145 may be formed by performing, e.g., a wet etching process on the first sacrificial layer 120, and a plurality of first recesses 145 connected to the first hole 140 may be formed to be spaced apart from each other in the first direction D1. Each of the first recesses 145 may have a shape of, e.g., a ring.

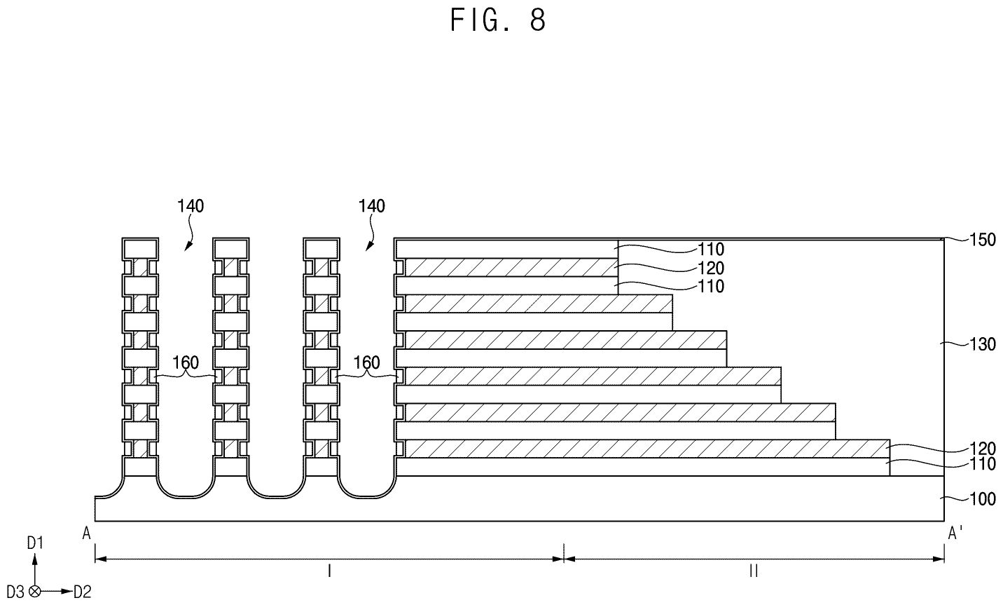

In FIG. 8, a second insulation layer 150 may be formed on inner walls of the first hole 140 and the first recess 145, an upper surface of the mold and an upper surface of the first insulating interlayer 130, a channel layer may be formed on the second insulation layer 150 to fill a portion of the first hole 140 and the first recess 145, and the channel layer may be partially removed to form a channel 160. The second insulation layer 150 may include an oxide, e.g., silicon oxide, and in some cases, may be merged with the first insulation layer 110.

The channel layer may be partially removed by, e.g., a wet etching process. In some implementations, a plurality of channels 160 may be spaced apart from each other in the first direction D1 along a sidewall of the first hole 140, and each of the channels 160 may have a shape of, e.g., a ring.

In some implementations, a plurality of channels 160 may be spaced apart from each other in the second direction D2 and the third direction D3 to form a channel array on the first region I of the substrate 100. The channel array may include a plurality of channel columns, each of which may include a plurality of channels 160 disposed in the second direction D2, spaced apart from each other in the third direction D3.

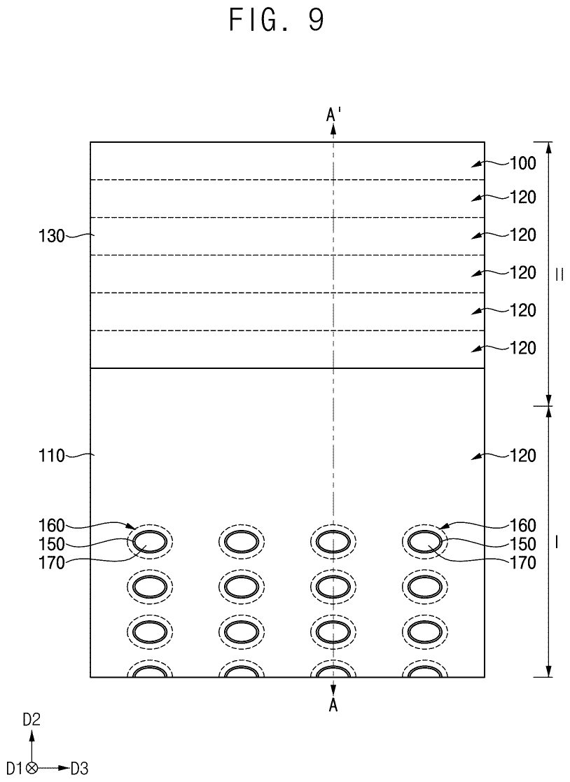

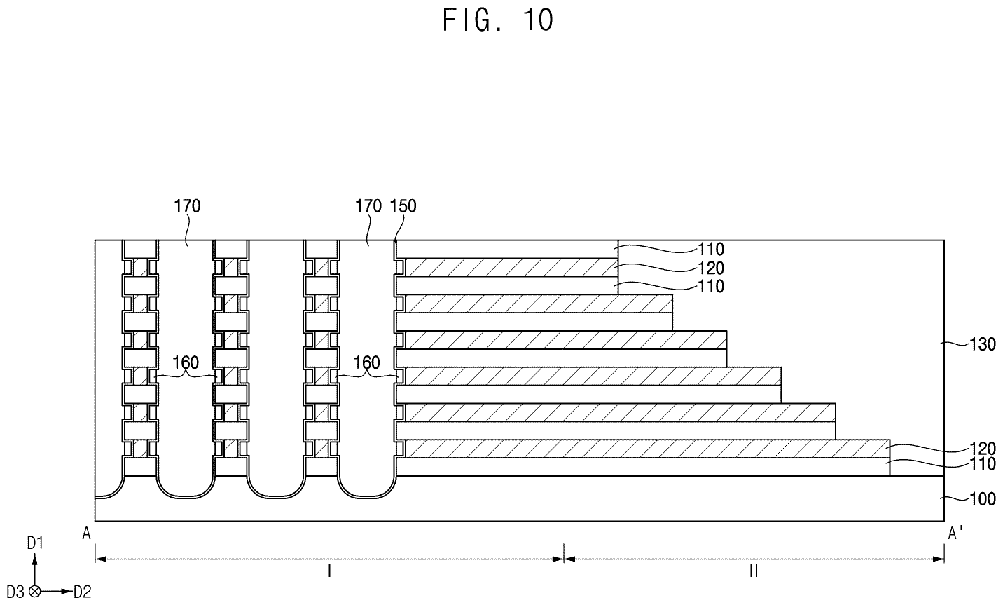

In FIGS. 9 and 10, a third insulation layer may be formed on the second insulation layer 150 and the channel 160 to fill the first hole 140, and a planarization process may be performed on the third insulation layer until the upper surface of the mold and an upper surface of the first insulating interlayer 130 are exposed to form a third insulation pattern 170 in the first hole 140. The third insulation pattern 170 may have a shape of a pillar extending in the first direction D1, and a plurality of third insulation patterns 170 may be spaced apart from each other in the second direction D2 and the third direction D3 on the first region I of the substrate 100.

During the planarization process, a portion of the second insulation layer 150 on the upper surface of the mold and the upper surface of the first insulating interlayer 140 may also be removed.

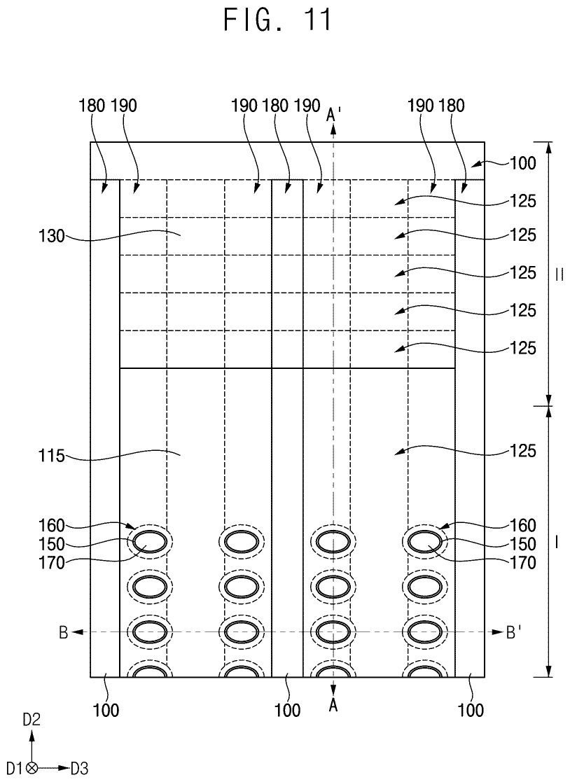

In FIGS. 11 to 13, a first opening 180 may be formed through the mold to expose the upper surface of the substrate 100, and the first opening 180 may also extend through the upper portion of the substrate 100.

In some implementations, the first opening 180 may extend to both opposite end portions of the mold in the second direction D2 on the first region I and the second region II of the substrate 100, and a plurality of first openings 180 may be spaced apart from each other in the third direction D3. As the first opening 180 is formed, the first insulation layer 110 may be divided into a plurality of first insulation patterns 115, each of which may extend in the second direction D2, spaced apart from each other in the third direction D3, and the first sacrificial layer 120 may be divided into a plurality of first sacrificial patterns 125, each of which may extend in the second direction D2, spaced apart from each other in the third direction D3.

In some implementations, each of the first openings 180 may be formed between neighboring ones of the channel columns in the third direction D3, and two channel columns may be disposed between neighboring ones of the first openings 180.

A lateral portion of the first sacrificial pattern 125 exposed by the first opening 180 and a portion of the second insulation layer 150 adjacent thereto may be removed to form a second recess 190 exposing a sidewall of the channel 160.

In some implementations, the second recess 190 may be formed by performing, e.g., a wet etching process on the first sacrificial pattern 125 and the second insulation layer 150, and a plurality of second recesses 190 connected to the first opening 180 may be formed to be spaced apart from each other in the first direction D1. Each of the second recesses 190 may extend in the second direction D2 on the first region I and the second region II of the substrate 100. In some implementations, the second recess 190 may expose most of each of the channels 160 included in the channel column adjacent to the first opening 180.

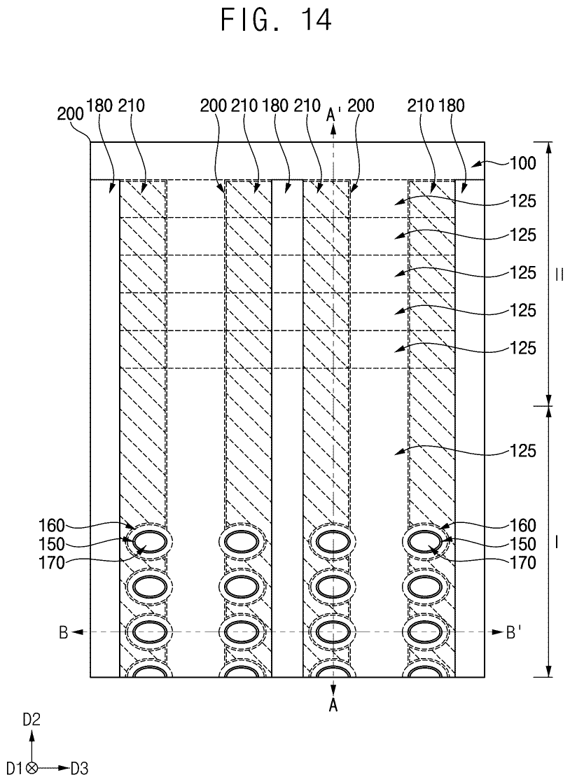

In FIGS. 14 to 16, a first gate insulation layer 200 may be formed on inner walls of the first opening 180 and the second recess 190, an upper surface of the third insulation pattern 170, an upper surface of the second insulation layer 150, the upper surface of the mold, and the upper surface of the first insulating interlayer 130, a first gate electrode layer may be formed on the first gate insulation layer 200 to fill a portion of the first opening 180 and the second recess 190, and the first gate electrode layer may be partially removed to form a first gate electrode 210. The first gate insulation layer 200 may include an oxide, e.g., silicon oxide, and in some cases, a portion of the second insulation layer 150 contacting the first gate insulation layer 200 may be merged thereto.

The first gate electrode layer may be partially removed by, e.g., a wet etching process. In some implementations, the first gate electrode 210 may extend in the second direction D2 at each of opposite sides in the third direction D3 of the first opening 180, and a plurality of first gate electrode layers may be formed to be spaced apart from each other in the third direction D3. Each of the first gate electrodes 210 may surround most of a sidewall of each of the channels 160 included in the channel column, and the first gate insulation layer 200 may be interposed between each of the first gate electrodes 210 and each of the channels 160.

A plurality of first gate electrodes 210 may be spaced apart from each other in the first direction D1 to form a first gate electrode structure. The first gate electrode structure may have a shape of a staircase having a length in the second direction D2 that may decrease from a lowermost level to an uppermost level in a stepwise manner. Hereinafter, each of opposite end portions of each of the first gate electrodes 210 in the first gate electrode structure that is not overlapped by upper ones of the first gate electrodes 210 in the first direction D1 may be referred to as a pad.

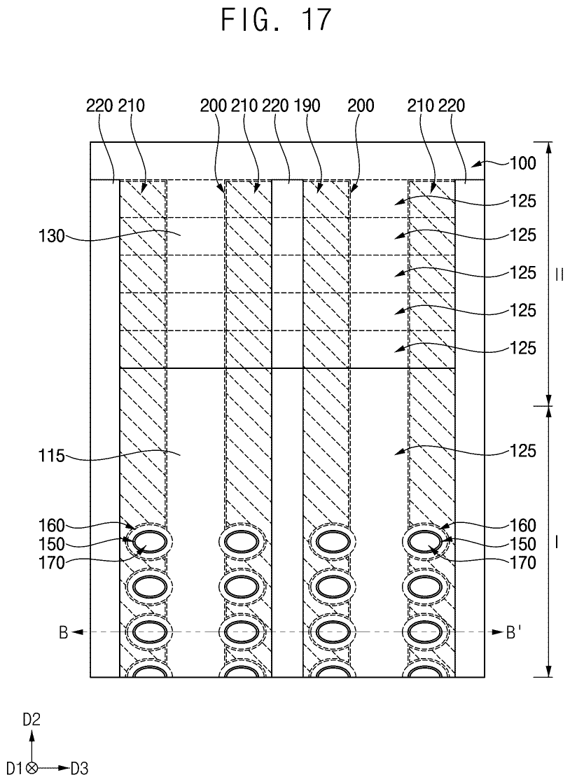

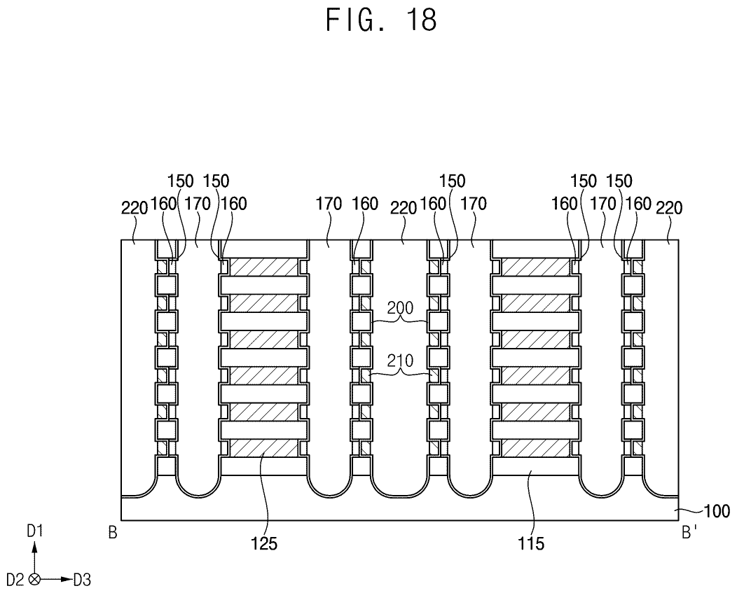

In FIGS. 17 and 18, a fourth insulation layer may be formed on the first gate insulation layer 200 and the first gate electrode 210 to fill the first opening 180, and a planarization process may be performed on the fourth insulation layer until the upper surfaces of the mold, the third insulation pattern 170, the second insulation layer 150, and the first insulating interlayer 130 are exposed to form a fourth insulation pattern 220 in the first opening 180.

The fourth insulation pattern 220 may extend in the second direction D2 on the first region I and the second region II of the substrate 100, and a plurality of fourth insulation patterns 220 may be spaced apart from each other in the third direction D3.

During the planarization process, a portion of the first gate insulation layer 200 on the upper surfaces of the mold, the third insulation pattern 170 and the first insulating interlayer 130 may also be removed.

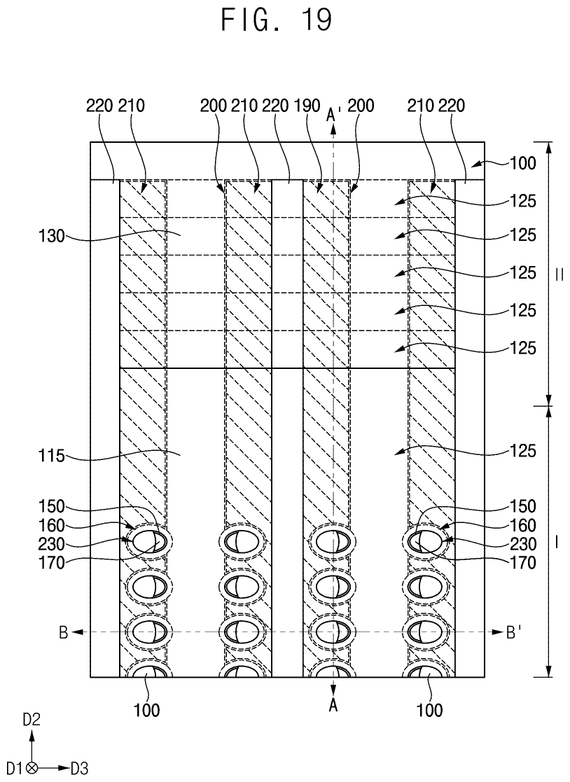

In FIGS. 19 to 21, a portion of the third insulation pattern 170 and a portion of the second insulation layer 150 adjacent thereto may be removed to form a second hole 230 exposing the upper surface of the substrate 100. As the second hole 230 is formed, sidewalls of the channel 160 and the first insulation pattern 115 may partially exposed.

In some implementations, a plurality of second holes 230 may be spaced apart from each other in the second direction D2 and the third direction D3 on the first region I of the substrate 100.

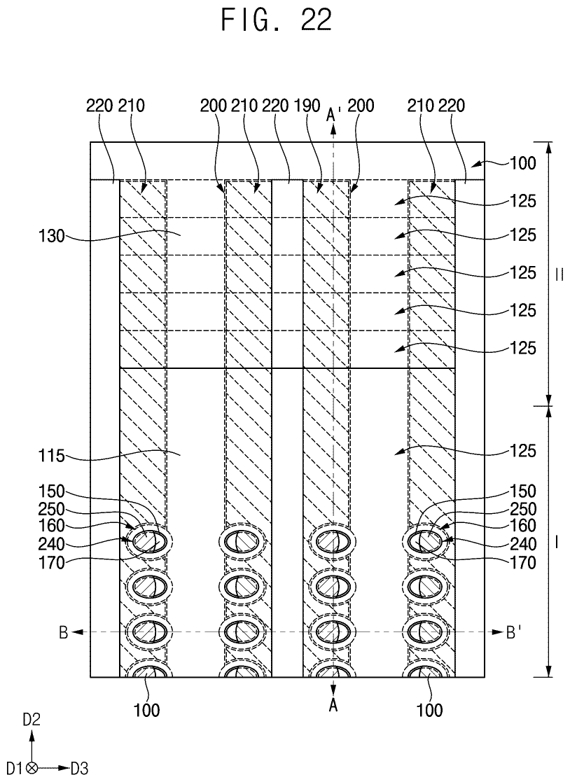

In FIGS. 22 to 24, a first ohmic contact pattern 240 may be formed on the sidewall of the channel 160 exposed by the second hole 230.

In some implementations, the first ohmic contact pattern 240 may be formed by forming a first metal layer on an inner wall of the second hole 230, the upper surfaces of the third and fourth insulation patterns 170 and 220, the upper surface of the second insulation layer 150, the upper surface of the mold and the upper surface of the first insulating interlayer 130, and performing a heat treatment process on the first metal layer so that a metal included in the first metal layer and a semiconductor material included in the channel 160 may be reacted with each other, and an unreacted portion of the first metal layer may be removed.

A plurality of first ohmic contact patterns 240 may be spaced apart from each other in the first direction D1 on the first region I of the substrate 100, and may also be spaced apart from each other in the second direction D2 and the third direction D3. Each of the first ohmic contact patterns 240 may have a shape of, e.g., a portion of a ring.

The first ohmic contact 240 may also be formed on the upper surface of the substrate 100 including a semiconductor material and exposed by the second hole 230.

A bit line layer may be formed on the substrate 100, the third insulation pattern 170 and the fourth insulation pattern 220, the second insulation layer 150, the mold and the first insulating interlayer 130 to fill the second hole 230, and a planarization process may be performed on the bit line layer until the upper surface of the first insulating interlayer 130 is exposed to form a bit line 250 in the second hole 230.

In some implementations, a plurality of bit lines 250 may be spaced apart from each other in the second direction D2 and the third direction D3 on the first region I of the substrate 100, and each of the bit lines 250 may have a shape of a pillar extending in the first direction D1. Each of the bit lines 250 may contact the first ohmic contact pattern 240, and may be electrically connected to the channels 160 disposed in the first direction D1 through the first ohmic contact pattern 240.

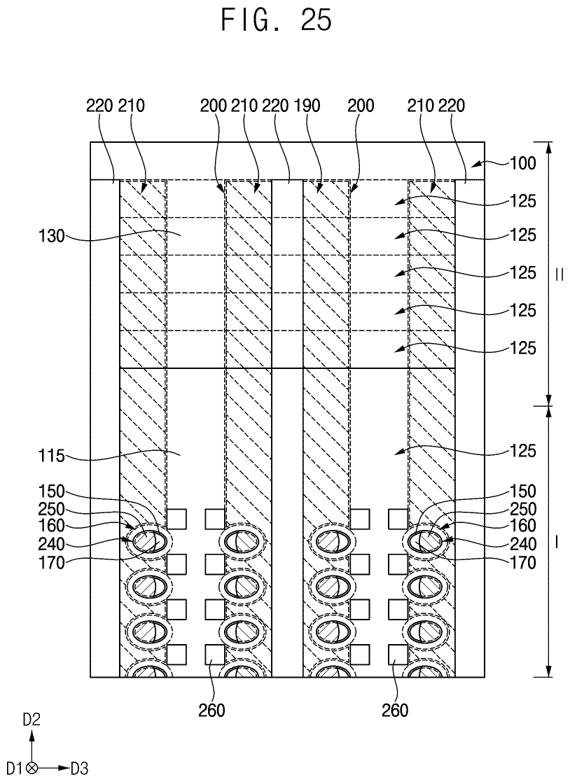

In FIG. 25, a third hole may be formed through the mold to expose the upper surface of the substrate 100 on the first region I of the substrate 100, and a fifth insulation pattern 260 may be formed in the third hole. The third hole may also extend through an upper portion of the substrate 100, and the fifth insulation pattern 260 in the third hole may extend through the upper portion of the substrate 100. In some implementations, the fifth insulation pattern 260 may have a pillar shape extending in the first direction D1, and a plurality of fifth insulation patterns 260 may be spaced apart from each other in the second direction D2 and the third direction D3 to form a fifth insulation pattern array.

The fifth insulation pattern array may include a plurality of fifth insulation pattern columns, each of which may include a plurality of fifth insulation patterns 260 disposed in the second direction D2, spaced apart from each other in the third direction D3. Each of the fifth insulation patterns 260 included in each of the fifth insulation pattern columns may extend through a portion of the mold between ones of the channels 160 of a corresponding one of the channel columns, and may contact a sidewall of the first gate insulation layer 200. Ones of the fifth insulation patterns 260 included in respective ones of the fifth insulation pattern columns neighboring in the third direction D3 may be aligned with each other in the third direction D3.

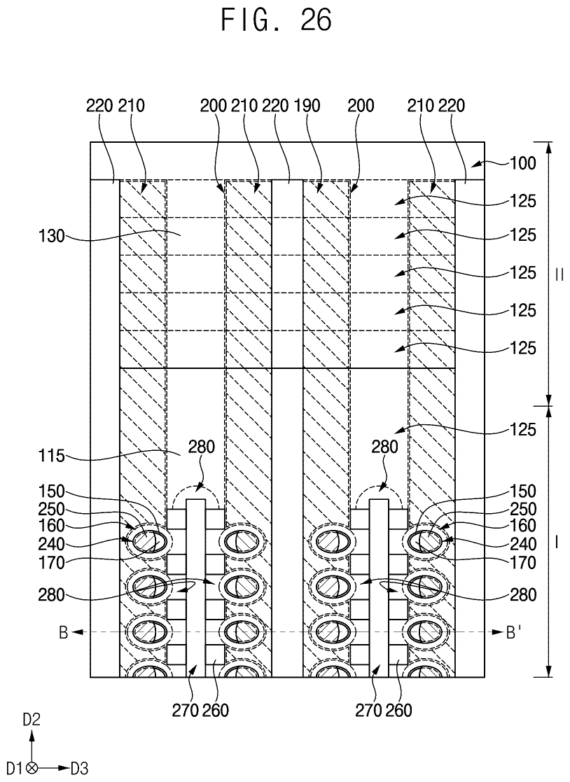

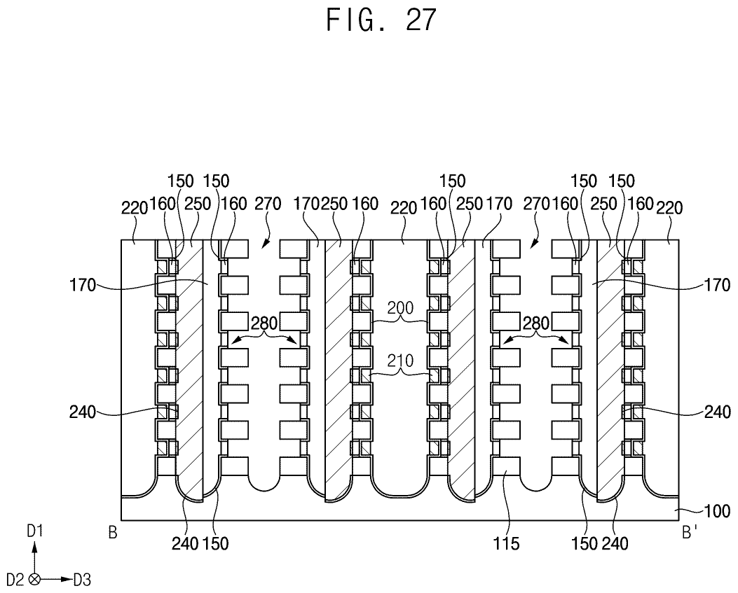

In FIGS. 26 and 27, a second opening 270 may be formed through the mold to expose the upper surface of the substrate 100 on the first region I of the substrate 100, and a portion of the first sacrificial pattern 125 exposed by the second opening 270 and a portion of the second insulation layer 150 adjacent thereto may be removed by, e.g., a wet etching process to form a third recess 280.

In some implementations, the second opening 270 may extend in the second direction D2 between neighboring ones of the fifth insulation pattern columns in the third direction D3, and may expose sidewalls of the fifth insulation patterns 260 included in the neighboring ones of the fifth insulation pattern columns. In some implementations, a plurality of third recesses 280 may be spaced apart from each other in the second direction D2 by the fifth insulation patterns 260, and may also be spaced apart from each other in the first direction D1 by the first insulation patterns 115. Each of the third recesses 280 may expose a sidewall, particularly, a sidewall in the third direction D3 of a corresponding one of the channels 160.

During the wet etching process, a portion of the first sacrificial pattern 125 at each of end portions in the second direction D2 of the second opening 270 may also be removed, and, in a plan view, the third recess 280 may have a shape of a semi-circle adjacent to each of the end portions of the second opening 270.

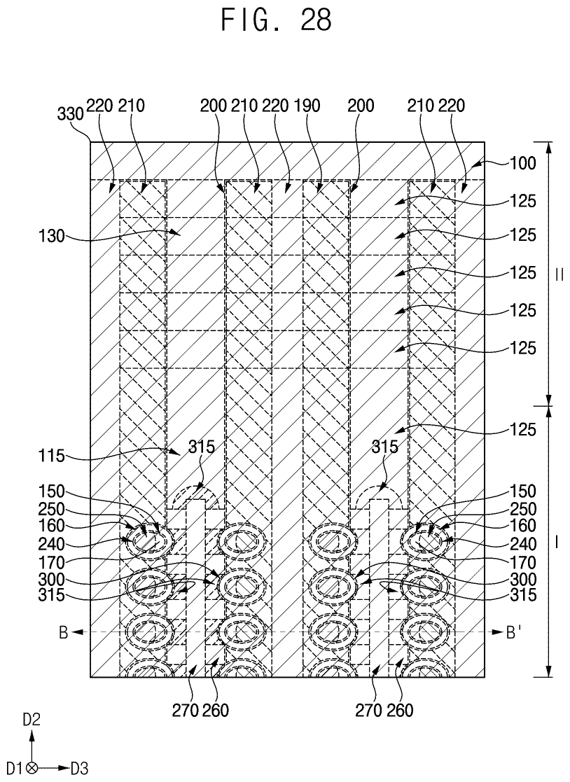

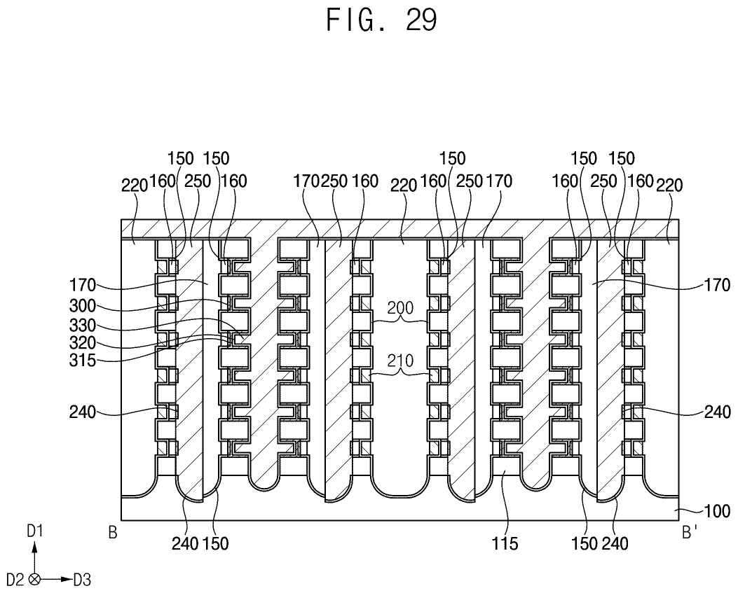

In FIGS. 28 and 29, a second ohmic contact pattern 300 may be formed on the sidewall of the channel 160 exposed by the third recess 280. In some implementations, the second ohmic contact pattern 300 may be formed by forming a second metal layer on inner walls of the second opening 270 and the third recess 280, the upper surfaces of the third insulation pattern 170 and the fourth insulation pattern 220, the upper surface of the second insulation layer 150, an upper surface of the bit line 250, the upper surface of the mold and the upper surface of the first insulating interlayer 130, and performing a heat treatment process on the second metal layer so that a metal included in the second metal layer and the semiconductor material included in the channel 160 may be reacted with each other, and an unreacted portion of the second metal layer may be removed.

A plurality of second ohmic contact patterns 300 may be spaced apart from each other in the first direction D1 on the first region I of the substrate 100, and may also be spaced apart from each other in the second direction D2 and the third direction D3. Each of the second ohmic contact patterns 240 may have a shape of, e.g., a portion of a ring. The second ohmic contact 300 may also be formed on the upper surface of the substrate 100 including the semiconductor material and exposed by the second opening 270.

A first capacitor electrode layer may be formed on the inner walls of the second opening 270 and the third recess 280, the upper surfaces of the third insulation pattern 170 and the fourth insulation pattern 220, the upper surface of the second insulation layer 150, the upper surface of the bit line 250, the upper surface of the mold and the upper surface of the first insulating interlayer 130, forming a second sacrificial layer on the first capacitor electrode layer to fill the third recess 280, and performing, e.g., a wet etching process on the second sacrificial layer to form a second sacrificial pattern in the third recess 280, and a portion of the first capacitor electrode layer at an outside of the third recess 280 may be exposed.

The exposed portion of the first capacitor electrode layer may be removed to form a first capacitor electrode 315 on the inner wall of the third recess 280, and the second sacrificial pattern may be removed. In some implementations, a plurality of first capacitor electrodes 315 may be spaced apart from each other in the first direction D1 on the first region I of the substrate 100, and may also be spaced apart from each other in the second direction D2 and the third direction D3 to form a first capacitor electrode array. The first capacitor electrode array may include a plurality of first capacitor electrode columns, each of which may include the first capacitor electrodes 315 spaced apart from each other in the second direction D2, spaced apart from each other in the third direction D3.

Each of the first capacitor electrodes 315 may contact sidewalls of the second ohmic contact pattern 300 and the second insulation layer 150, and may be electrically connected to the channel 160 through the second ohmic contact pattern 300. The first capacitor electrode 315 may also be formed in the third recess 280 adjacent to each of end portions of the second opening 270 in the second direction D2, which may have a shape of, e.g., a semi-circle in a plan view.

A dielectric layer 320 may be formed on the inner wall of the second opening 270, the upper surfaces of the third insulation pattern 170 and the fourth insulation pattern 220, the upper surface of the second insulation layer 150, the upper surface of the bit line 250, the upper surface of the mold and the upper surface of the first insulating interlayer 130, and a second capacitor electrode layer 330 may be formed on the dielectric layer 320 to fill the second opening 270.

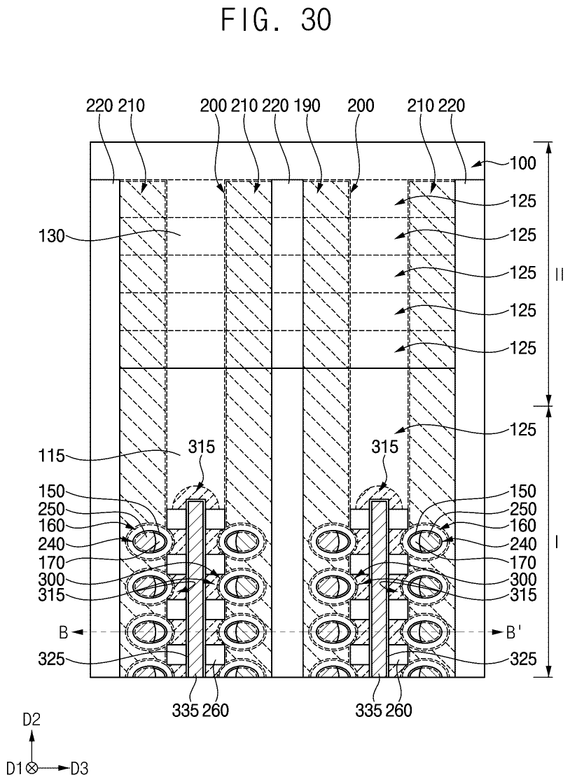

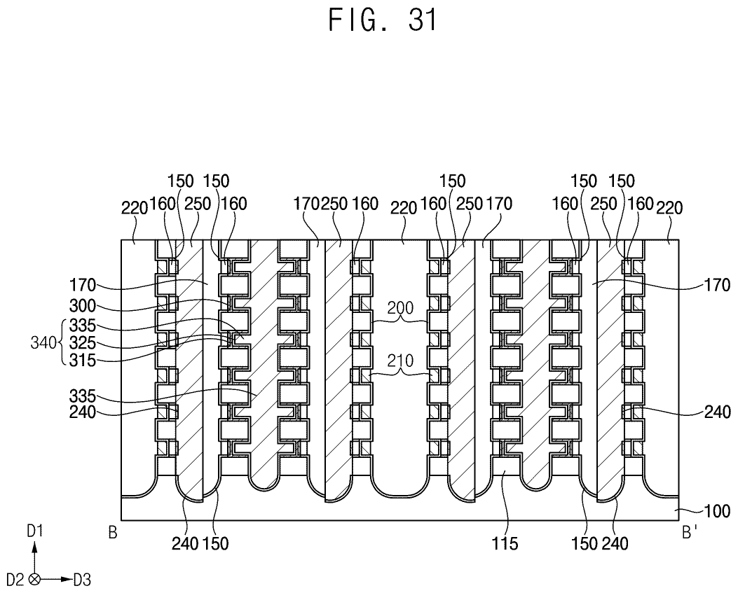

In FIGS. 30 and 31, a planarization process may be performed on the second capacitor electrode layer 330 and the dielectric layer 320 until the upper surface of the mold is exposed so that the second capacitor electrode layer 330 and the dielectric layer 320 may be transformed into a second capacitor electrode 335 and a dielectric pattern 325, respectively. The first capacitor electrode 315, the dielectric pattern 325, and the second capacitor electrode 335 may collectively form a capacitor structure 340.

In some implementations, the second capacitor electrode 335 may extend in the second direction D2 on the first region I of the substrate 100, and a plurality of second capacitor electrodes 335 may be spaced apart from each other in the third direction D3. The second capacitor electrode 335 may include an extension portion extending in the second direction D2 and a first protrusion portion protruding in the third direction D3 from each of opposite sidewalls in the third direction D3 of the extension portion and facing the sidewall of the channel 160. In some implementations, the second capacitor electrode 335 may include a plurality of first protrusion portions spaced apart from each other in the second direction D2 and the third direction D3, and may also be spaced apart from each other in the first direction D1. The second capacitor electrode 335 may further include a second protrusion portion protruding from each of end portions in the second direction D2 of the extension portion and having a shape of a semi-circle in a plan view.

In FIGS. 1 to 3, a second insulating interlayer 370 may be formed on the third insulation pattern 170, the fourth insulation pattern 220, and the fifth insulation pattern 260, the dielectric pattern 325, the second capacitor electrode 335, the second insulation layer 150, the bit line 250, the mold and the first insulating interlayer 130, and a first contact plug 380 extending through the first insulating interlayer 130 and the second insulating interlayer 370 to contact a pad of a corresponding one of the first gate electrodes 210 and a second contact plug extending through the second insulating interlayer 370 to contact the upper surface of a corresponding one of the bit lines 250 may be formed. A third contact plug may also be formed through the second insulating interlayer 370 to contact an upper surface of a corresponding one of the second capacitor electrodes 335.

By the above processes, a semiconductor device may be manufactured.

As illustrated above, the mold including the first insulation layer 110 and the first sacrificial layer 120 may be formed on the substrate 100, the first hole 140 may be formed through the mold, the portion of the first sacrificial layer 120 adjacent to the first hole 140 may be removed to form the first recess 145, and the channel 160 may be formed in the first recess 145. The third insulation pattern 170 may be formed in the first hole 140, the first opening 180 may be formed through the mold, and the portion of the first sacrificial layer 120 adjacent to the first opening 180 may be removed to form the second recess 190, and the first gate electrode 210 may be formed in the second recess 190.

The third insulation pattern 170 may be partially removed to form the second hole 230, the bit line 250 may be formed in the second hole 230, the second opening 270 may be formed through the mold, the portion of the first sacrificial layer 120 adjacent to the second opening 270 may be removed to form the third recess 280 exposing the sidewall of the channel 160, and the first capacitor electrode 315 may be formed in the third recess 280.

Accordingly, the channel 160, the first gate electrode 210, and the first capacitor electrode 315 may be formed at the same level, so that the vertical thickness thereof may be reduced. Accordingly, the formation of the channel 160, the first gate electrode 210, and the first capacitor electrode 315 may be easily performed.

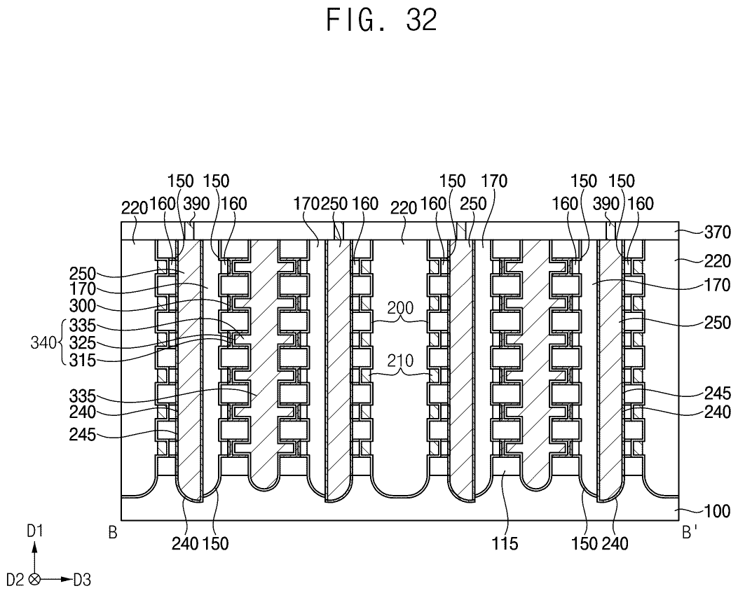

FIG. 32 is a cross-sectional view illustrating an example of a semiconductor device in accordance with some implementations. FIG. 32 may correspond to FIG. 3. This semiconductor device may be substantially the same as or similar to that of FIGS. 1 to 3, except for some elements, and repeated explanations are omitted herein.

In FIG. 32, the semiconductor device may further include a metal pattern 245 covering the sidewall of the bit line 250. For example, after performing the processes illustrated with respect to FIGS. 22 to 24 to form the first ohmic contact pattern 240 on the sidewall of the channel 160 exposed by the second hole 230, the unreacted portion of the first metal layer may not be removed but remain, which may be referred to as the metal pattern 245.

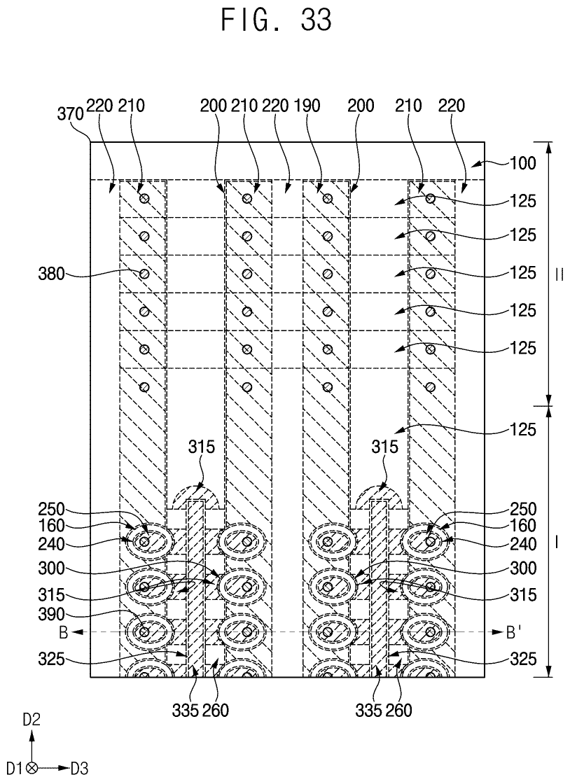

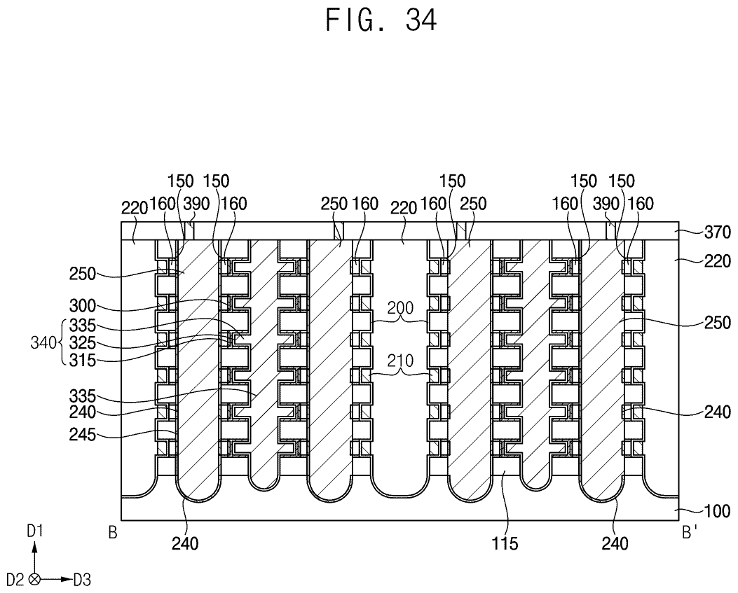

FIGS. 33 and 34 are a plan view and a cross-sectional view illustrating an example of a semiconductor device in accordance with some implementations. FIGS. 33 and 34 may correspond to FIGS. 1 and 3. This semiconductor device may be substantially the same as or similar to that of FIGS. 1 to 3, except for some elements, and thus repeated explanations are omitted herein.

In FIGS. 33 and 34, the semiconductor device may not include the third insulation pattern 170. For example, when the processes illustrated with reference to FIGS. 19 to 21 are performed to form the second hole 230, the third insulation pattern 170 may be entirely removed, and the first ohmic contact pattern 240 and the bit line 250 may be formed in the second hole 230. Accordingly, the first ohmic contact pattern 240 between the bit line 250 and the channel 160 may have a shape of, e.g., a ring, and may entirely surround the sidewall of the bit line 250 at the same level as the first ohmic contact pattern 240. Additionally, the channel 160 may also entirely surround the sidewall of the bit line 250 at the same level as the channel 160.

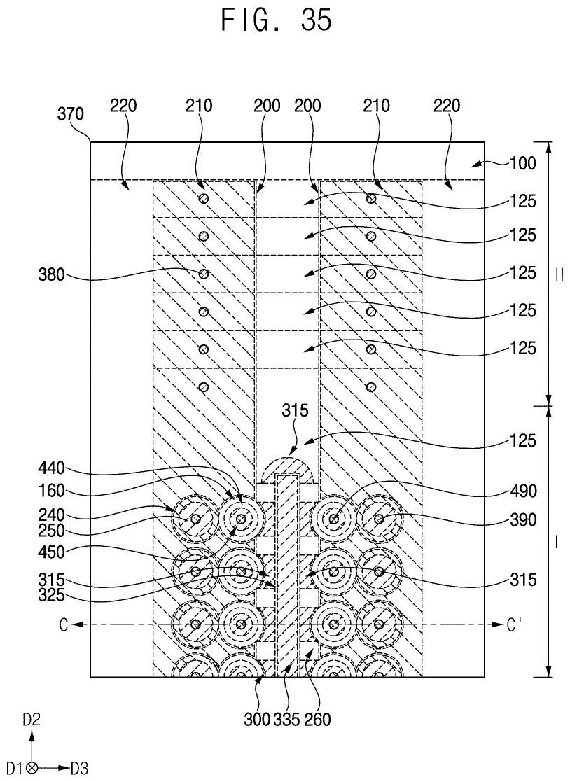

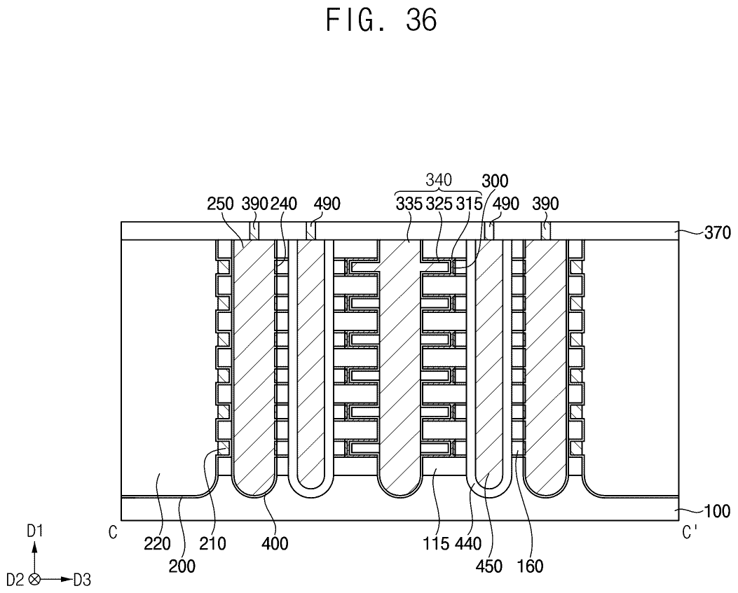

FIGS. 35 and 36 are a plan view and a cross-sectional view illustrating an example of a semiconductor device in accordance with some implementations, FIGS. 35 and 36 may correspond to FIGS. 1 and 3. This semiconductor device may be substantially the same as or similar to that of FIGS. 1 to 3, except for some elements, and thus repeated explanations are omitted herein.

In FIGS. 35 and 36, the semiconductor device may further include a second gate electrode 450, a second gate insulation pattern 440, and the fourth contact plug 490. The second gate electrode 450 may be disposed on the first region I of the substrate 100, and may extend through the first gate electrode structure and the first insulation patterns 115 in the first direction D1. In some implementations, the second gate electrode 450 may extend through a portion of the first gate electrode structure adjacent to the bit line 250 in the third direction D3. The second gate electrode 450 may serve as a back gate of the semiconductor device.

A plurality of second gate electrodes 450 may be spaced apart from each other in the second direction D2 and the third direction D3 on the first region I of the substrate 100 to form a second gate electrode array. In some implementations, the second gate electrode array may include a plurality of second gate electrode columns, each of which may include a plurality of second gate electrodes 450 disposed in the second direction D2, spaced apart from each other in the third direction D3. Two second gate electrode columns may be formed between neighboring ones of the fourth insulation patterns 220 in the third direction D3, and may be formed at opposite sides, respectively, in the third direction D3 of the second capacitor electrode 335 to be symmetrical with reference to the second capacitor electrode 335.

The second gate insulation pattern 440 may cover a sidewall and a lower surface of the second gate electrode 450.

Unlike that shown in FIGS. 1 to 3, the channel 160 may contact and surround a sidewall of the second gate insulation pattern 440 on the sidewall of the second gate electrode 450, instead of surrounding the sidewall of the bit line 250. The channel 160 may contact the first ohmic contact pattern 240 surrounding the sidewall of the bit line 250, and may be electrically connected to the bit line 250 through the first ohmic contact pattern 240.

The first capacitor electrode 315 of the capacitor structure 340 may be electrically connected to the channel 160 through the second ohmic contact pattern 300 on the sidewall in the third direction D3 of the channel 160 surrounding the sidewall of the second gate insulation pattern 440.

The fourth contact plug 490 may extend through the second insulating interlayer 370, and may contact an upper surface of the second gate electrode 450.

Each of the second gate electrode 450 and the fourth contact plug 490 may include, e.g., a metal, a metal nitride, a metal silicide, doped polysilicon, etc., and the second gate insulation pattern 440 may include an oxide, e.g., silicon oxide.

In some implementations, the channel 160 may surround the sidewall of the second gate insulation pattern 440 on the sidewall of the second gate electrode 450, and the first capacitor electrodes 315, the channels 160, the second gate electrodes 450, and the bit lines 250 at opposite sides, respectively, in the third direction D3 may be symmetrical with reference to the second capacitor electrode 335 extending in the second direction D2. Additionally, the bit line 250, the first capacitor electrode 315, and the portion of the channel 160 therebetween may be disposed in the third direction D3 that is substantially perpendicular to the second direction D2, which is the extension direction of the first gate electrode 210.

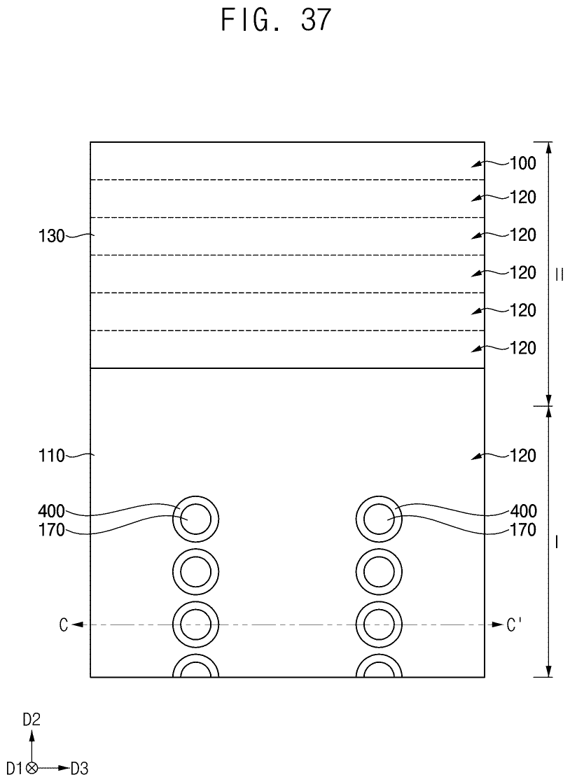

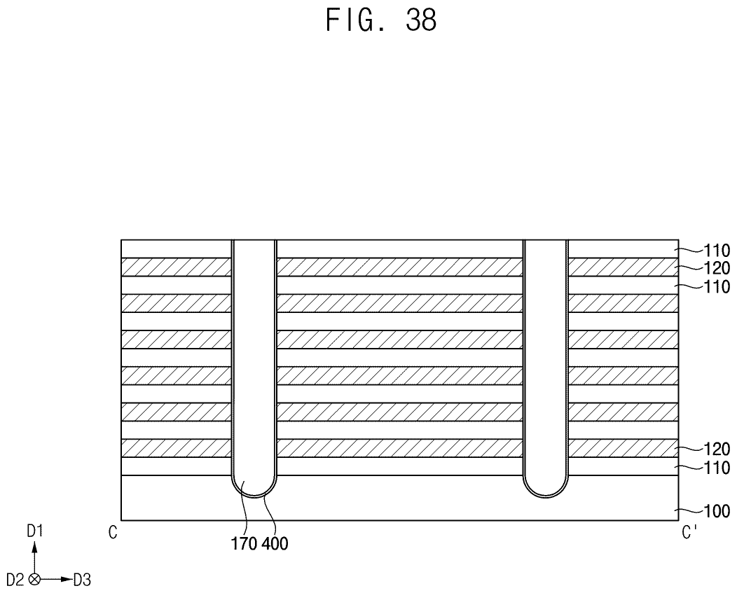

FIGS. 37 to 48 are plan views and cross-sectional views illustrating an example of a method of manufacturing a semiconductor device in accordance with some implementations. Particularly, FIGS. 37, 39, 41, 43, 45, and 47 are the plan views, and FIGS. 38, 40, 42, 44, 46, and 48 are cross-sectional views taken along lines C-C′ of corresponding plan views, respectively. In some implementations, the method may include processes substantially the same as or similar to those illustrated with respect to FIGS. 4 to 31 and FIGS. 1 to 3, and repeated explanations thereof are omitted herein.

In FIGS. 37 and 38, processes substantially the same as or similar to those illustrated with respect to FIGS. 4 to 6 may be performed to form the first hole 140 on the first region I of the substrate 100, and the third insulation pattern 170 and a sixth insulation pattern 400 covering a sidewall, and a lower surface of the third insulation pattern 170 may be formed in the first hole 140.

In some implementations, a plurality of first holes 140 may be spaced apart from each other in the second direction D2 and the third direction D3 to form a first hole array, and the first hole array may include a plurality of first hole columns, each of which may include a plurality of first holes 140 disposed in the second direction D2, spaced apart from each other in the third direction D3.

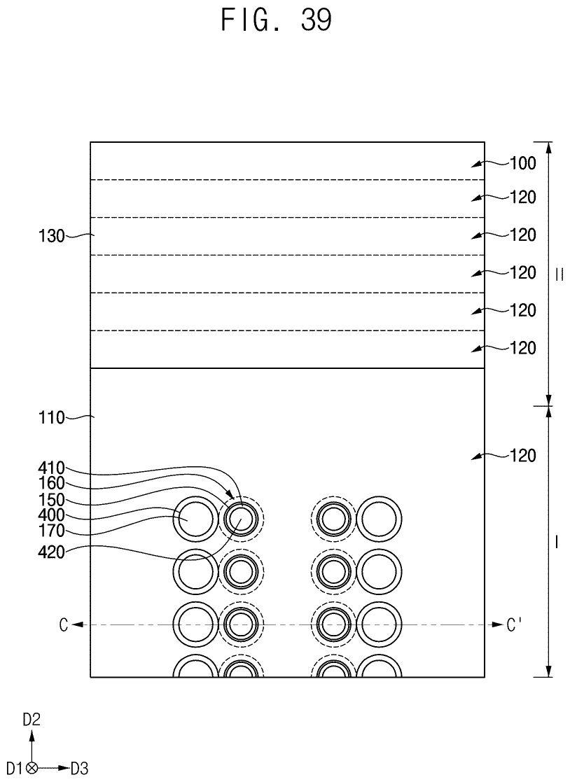

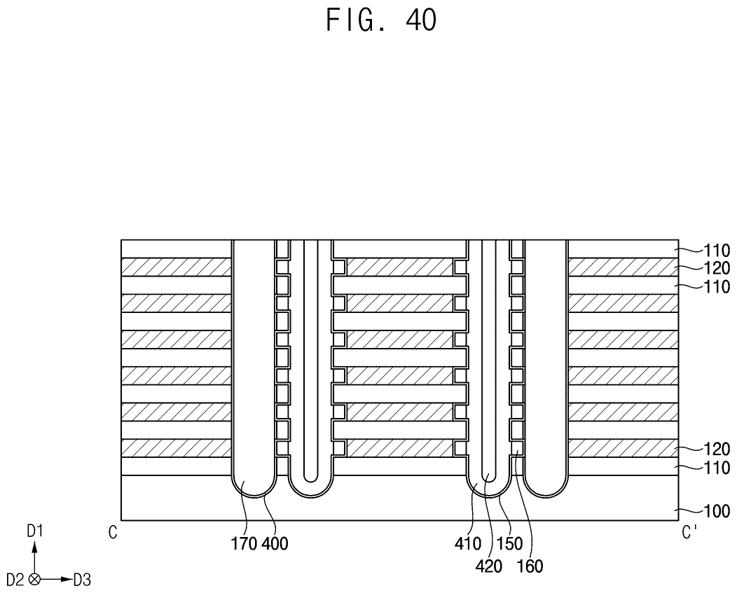

In FIGS. 39 and 40, a portion of the mold on the first region I of the substrate 100 may be etched to form a fourth hole extending in the first direction DI to expose the upper surface of the substrate 100.

In some implementations, a plurality of fourth holes may be spaced apart from each other in the second direction D2 and the third direction D3 on the first region I of the substrate 100, and the fourth holes may be formed to be adjacent to the first holes 140, respectively, in the third direction D3.

Processes substantially the same as or similar to those illustrated with respect to FIGS. 7 and 8 may be performed to form a fourth recess connected to the fourth hole, the second insulation layer 150 may be formed on inner walls of the fourth hole and the fourth recess, the upper surface of the mold and the upper surface of the first insulating interlayer 130, and the channel 160 may be formed in the recess.

The fourth recess may be formed by removing the portion of the first sacrificial layer 120 exposed by the fourth hole, and a portion of the sixth insulation pattern 400 adjacent to the first sacrificial layer 120 may also be removed to expose a sidewall of a portion of the third insulation pattern 170. Accordingly, a portion of the second insulation layer 150 on the inner wall of the fourth recess may contact the exposed portion of the third insulation pattern 170.

A third sacrificial layer may be formed on the second insulation layer 150 and the channel 160 to partially fill the fourth hole, a fourth sacrificial layer may be formed on the third sacrificial layer to fill a remaining portion of the fourth hole, and a planarization process may be performed on the third and fourth sacrificial layers until the upper surface of the mold and the upper surface of the first insulating interlayer 130 are exposed, so that third and fourth sacrificial patterns 410 and 420 may be formed in the fourth hole.

The third sacrificial pattern 410 may include an insulating material, e.g., silicon oxycarbide, silicon oxynitride, silicon nitride, etc., and the fourth sacrificial pattern 420 may include an oxide, e.g., silicon oxide.

During the planarization process, the portion of the second insulation layer 150 on the upper surface of the mold and the upper surface of the first insulating interlayer 130 may also be removed.

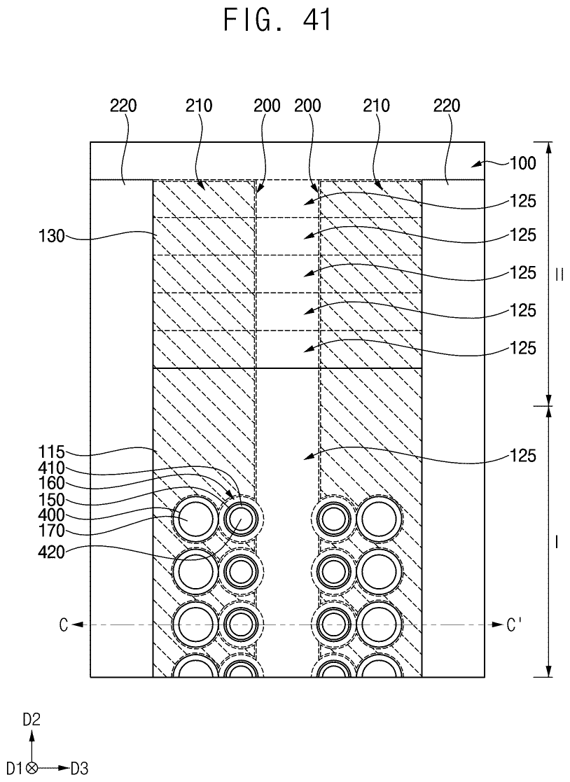

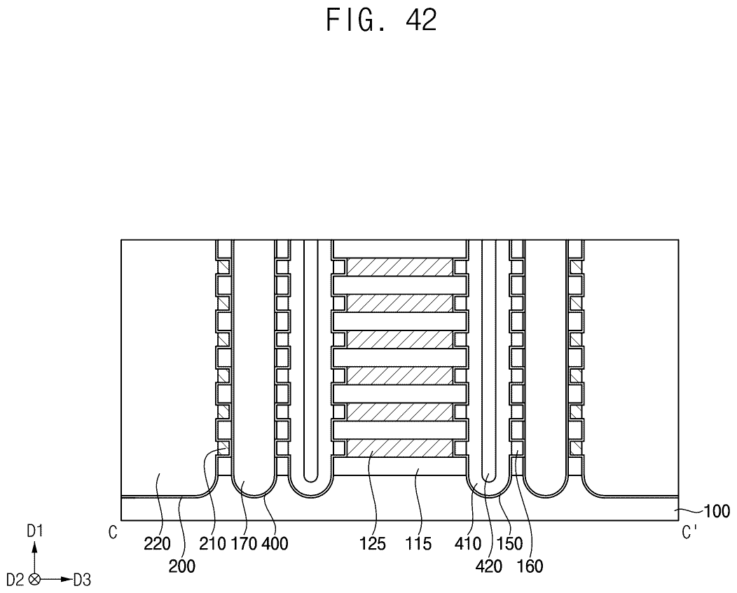

In FIGS. 41 and 42, processes substantially the same as or similar to those illustrated with respect to FIGS. 11 to 18 may be performed to form the first gate insulation layer 200, the first gate electrode 210, and the fourth insulation pattern 220. The first gate insulation layer 200 may contact sidewalls of the sixth insulation pattern 400, the channel 160 and the first sacrificial pattern 125.

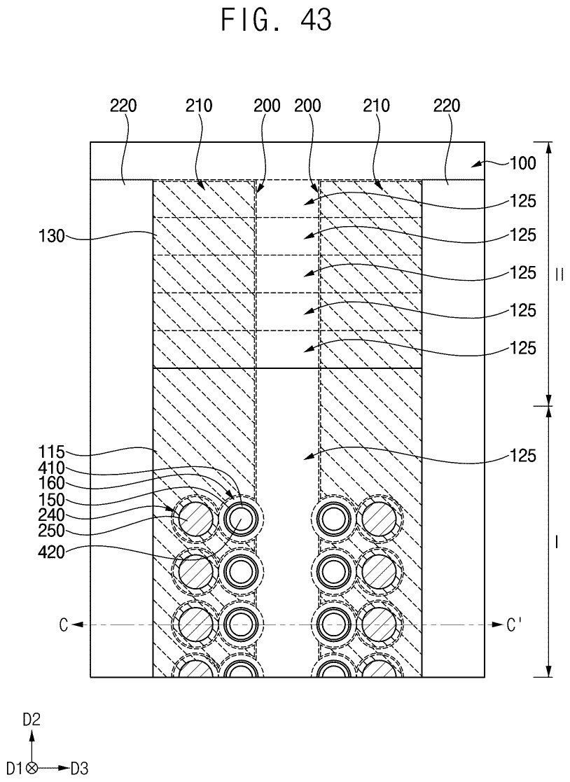

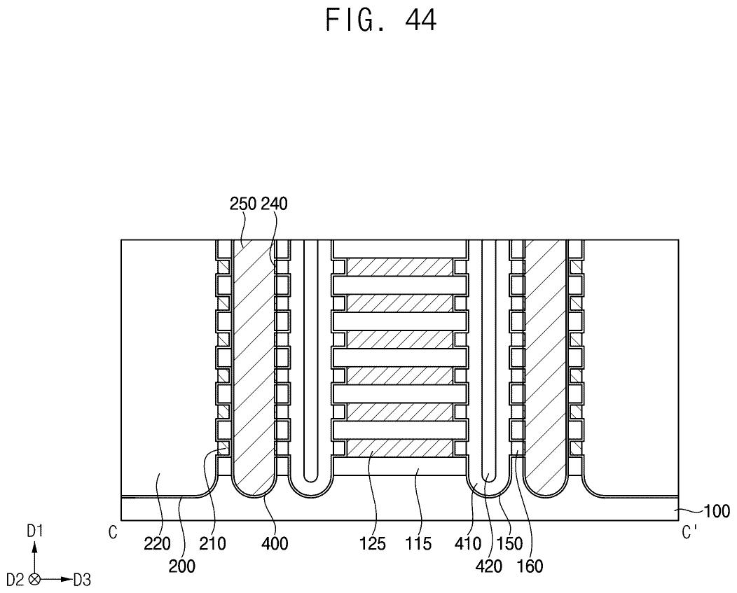

In FIGS. 43 and 44, processes substantially the same as or similar to those illustrated with respect to FIGS. 19 to 24 may be performed to form the first ohmic contact pattern 240 and the bit line 250.

In FIGS. 43 and 44, after entirely removing the third insulation pattern 170, the first ohmic contact pattern 240 and the bit line 250 may be formed, however, the inventive concept may not be limited thereto. For example, as illustrated in FIGS. 22 to 24, after partially removing the third insulation pattern 170, the first ohmic contact pattern 240 and the bit line 250 may be formed.

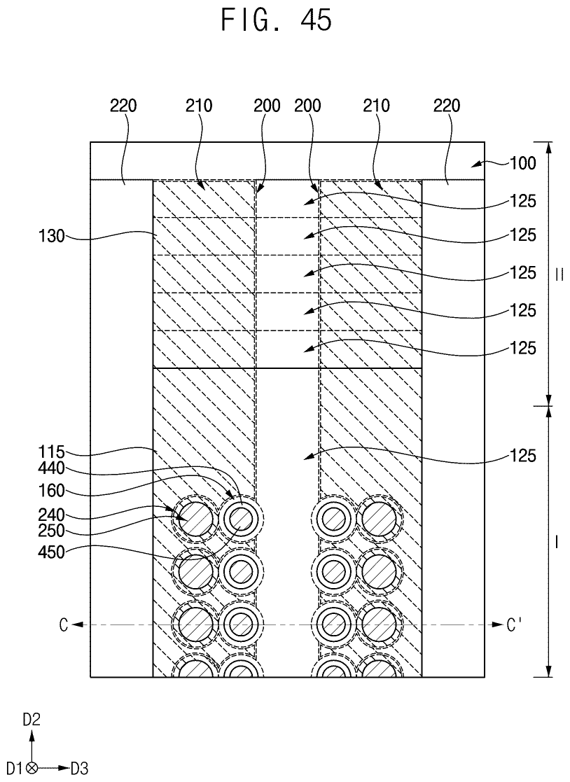

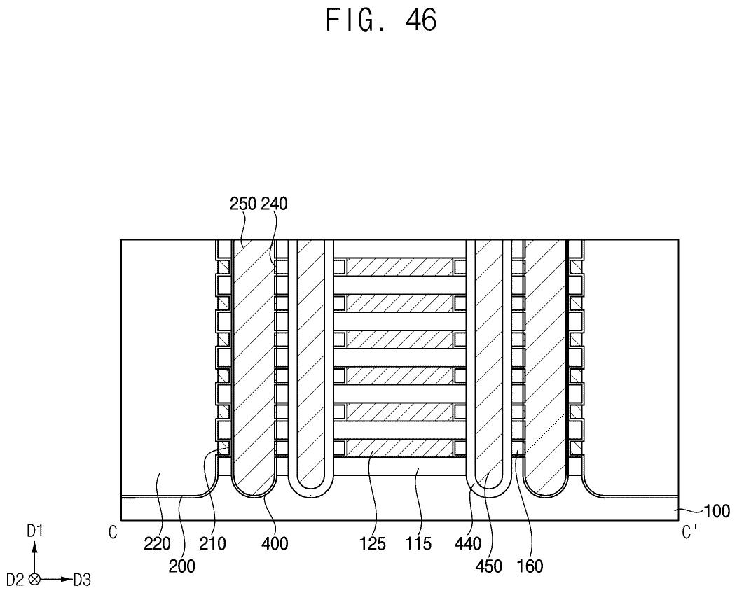

In FIGS. 45 and 46, the third sacrificial pattern 410 and the fourth sacrificial pattern 420 may be removed to form a fifth hole exposing the sidewall of the channel 160 and the upper surface of the substrate 100, and a portion of the second insulation layer 150 on the sidewall of the first insulation pattern 115 may also be removed to expose the sidewall of the first insulation pattern 115.

A second gate insulation layer may be formed on an inner wall of the fifth hole, the upper surface of the bit line 250, an upper surface of the sixth insulation pattern 400, the upper surface of the mold and the upper surface of the first insulating interlayer 130, a second gate electrode layer may be formed on the second gate insulation layer, and a planarization process may be performed on the second gate electrode layer and the second gate insulation layer to form a second gate electrode 450 and a second gate insulation pattern 440, respectively, in the fifth hole.

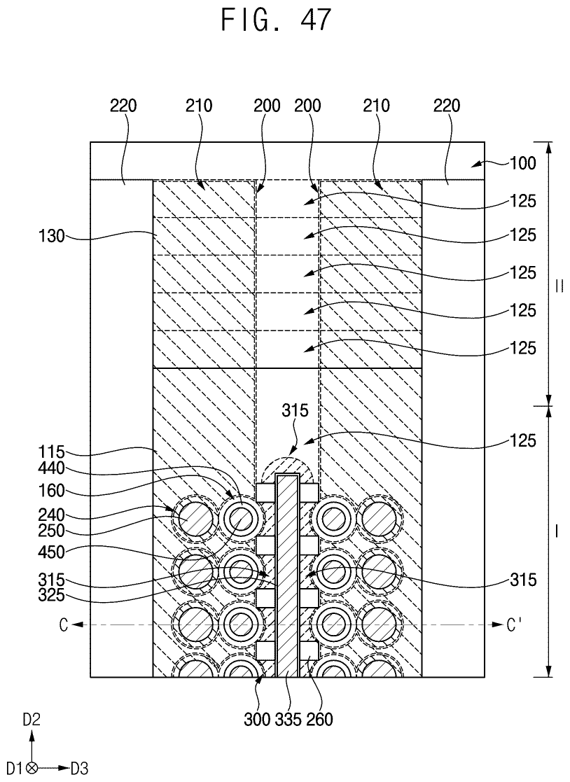

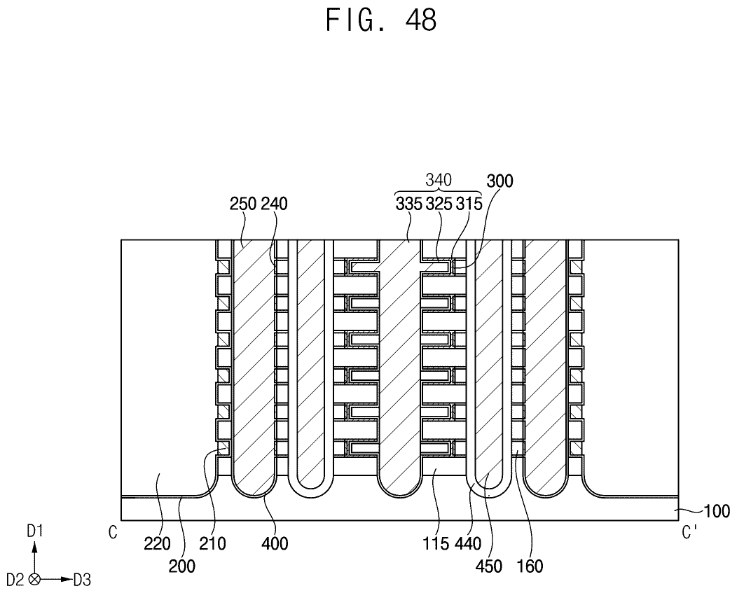

In FIGS. 47 and 48, processes substantially the same as or similar to those illustrated with respect to FIGS. 25 to 31 may be performed to form the fifth insulation pattern 260, the second ohmic contact pattern 300 and the capacitor structure 340. The first capacitor electrode 315 of the capacitor structure 340 may be electrically connected to the channel 160 through the second ohmic contact pattern 300.

In FIGS. 35 and 36, processes substantially the same as or similar to those illustrated with respect to FIGS. 1 to 3 may be performed to complete the fabrication of the semiconductor device. However, a fourth contact plug 490 extending through the second insulating interlayer 370 to contact an upper surface of the second gate electrode 450 may be further formed.

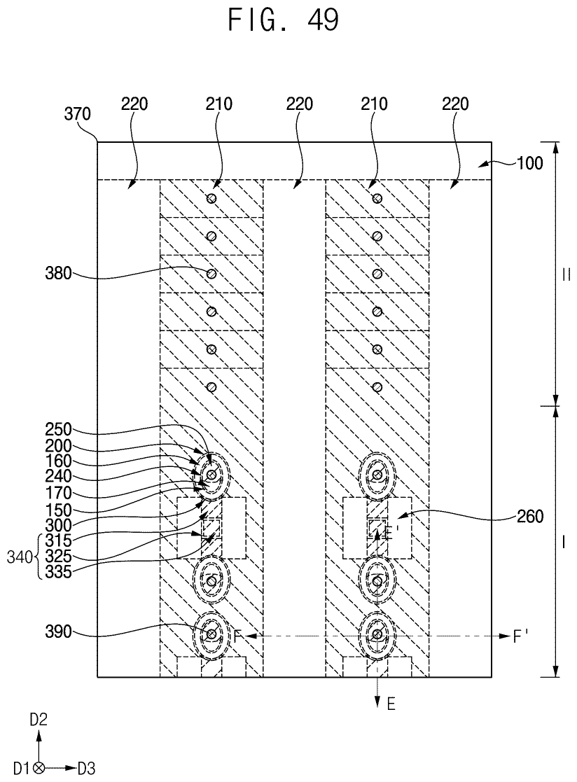

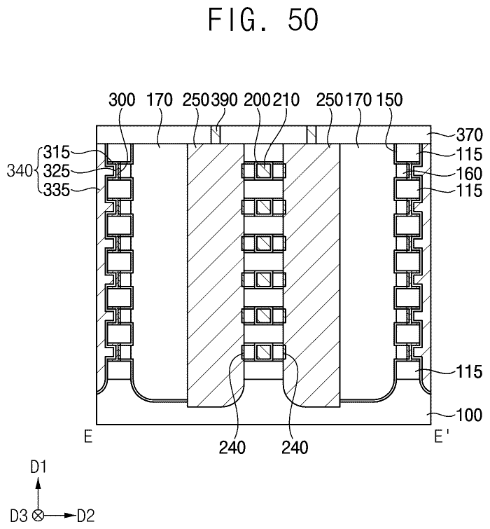

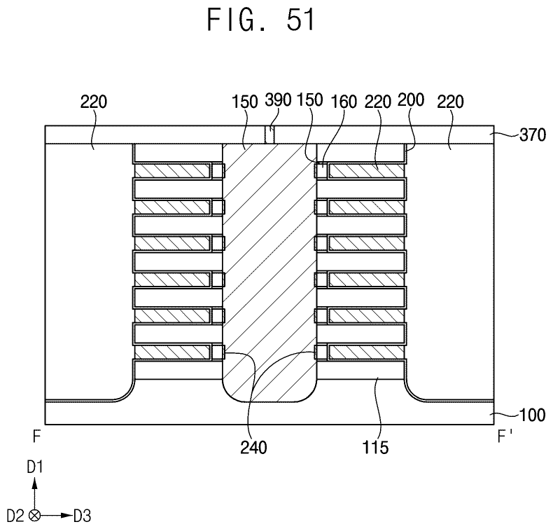

FIGS. 49 to 51 are a plan view and cross-sectional views illustrating an example of a semiconductor device in accordance with some implementations. The semiconductor device may be substantially the same as or similar to that of FIGS. 1 to 3, except for some elements, and repeated explanations are omitted herein.

In FIGS. 49 to 51, unlike that of FIGS. 1 to 3, the bit line 250, the first capacitor electrode 315, and the portion of the channel 160 therebetween may be disposed in the second direction D2, which is the extension direction of the first gate electrode 210.

In some implementations, a single first gate electrode structure may be disposed between neighboring ones of the fourth insulation patterns 220 in the third direction D3, and a single bit line column including a plurality of bit lines 250 disposed in the second direction D2, a single channel column including a plurality of channels 160 disposed in the second direction D2 and a single capacitor structure column including a plurality of capacitor structures 340 may extend through the single first gate electrode structure.

The bit line column may include a plurality of bit line pairs, each of which may include two bit lines 250 spaced apart from each other in the second direction D2 by a first distance, spaced apart from each other in the second direction D2 by a second distance greater than the first distance. However, a single bit line 250 may be disposed at each of opposite ends in the second direction D2 of the bit line column. FIGS. 49 to 51 show the bit line 250 at an end of the bit line column and a bit line pair adjacent to the bit line 250.

The channel 160 may surround sidewalls of the bit line 250 and the third insulation pattern 170 contacting the bit line 250, and the first ohmic contact pattern 240 may be disposed between the channel 160 and the bit line 250.

The capacitor structure 340 may be disposed between neighboring ones of the bit line pairs in the second direction D2. The second capacitor electrode 315 of the capacitor structure 340 may include the extension portion extending in the first direction D1 between the neighboring ones of the bit line pairs and the first protrusion portion protruding in the second direction D2 from each of opposite sidewalls in the second direction D2 of the extension portion. Thus, two first capacitor electrodes 315 may be spaced apart from each other in the second direction D2 between the bit line pairs.

In the semiconductor device, the first capacitor electrodes 315, the channels 160, and the bit lines 250 at opposite sides, respectively, of the second capacitor electrode 335 in the second direction D2 may be symmetrical with reference to an imaginary line extending in the third direction D3 and passing the extension portion of the second capacitor electrode 335.

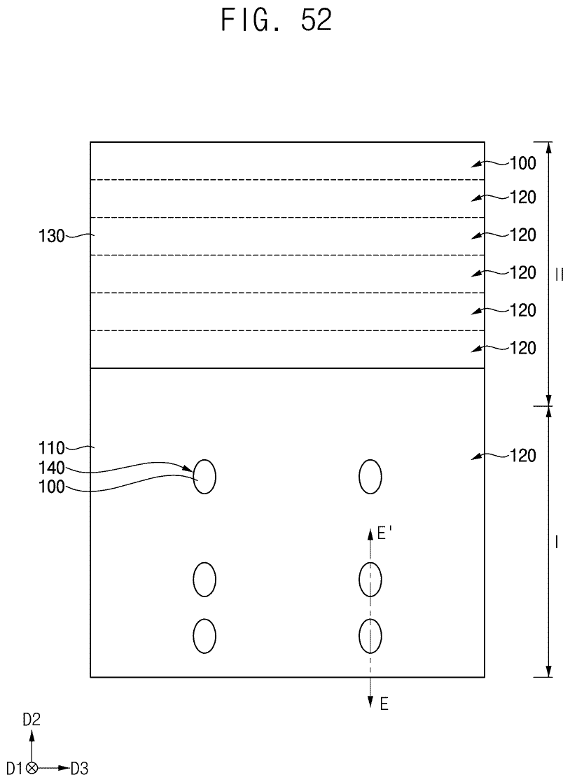

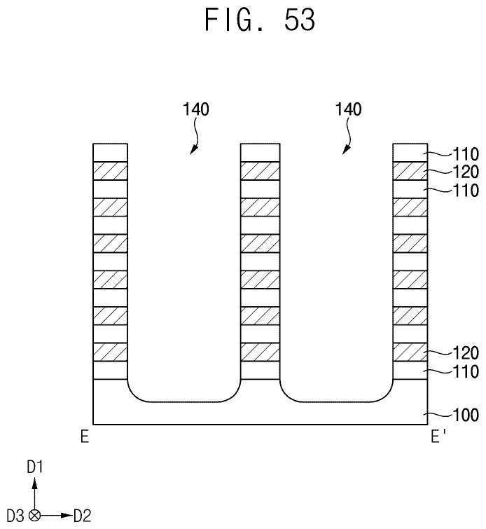

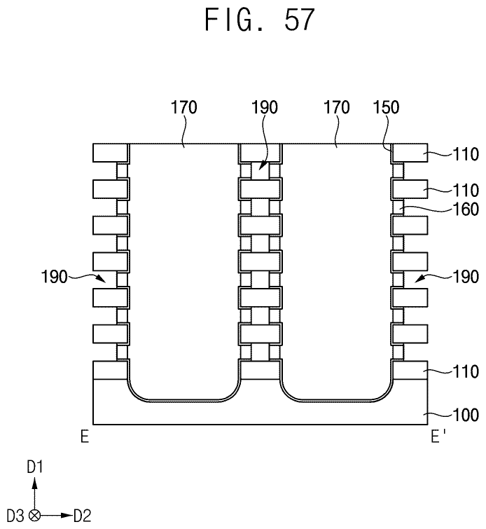

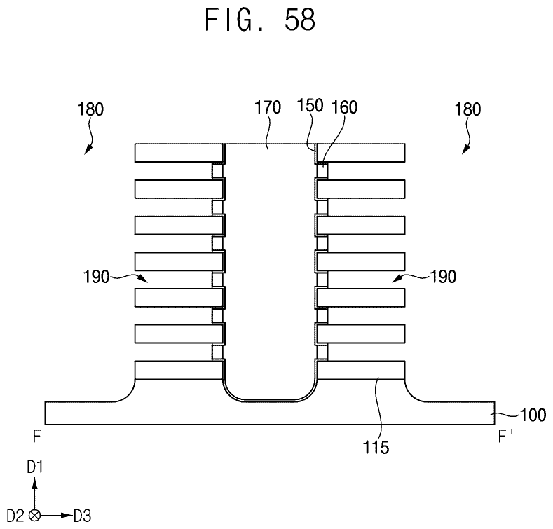

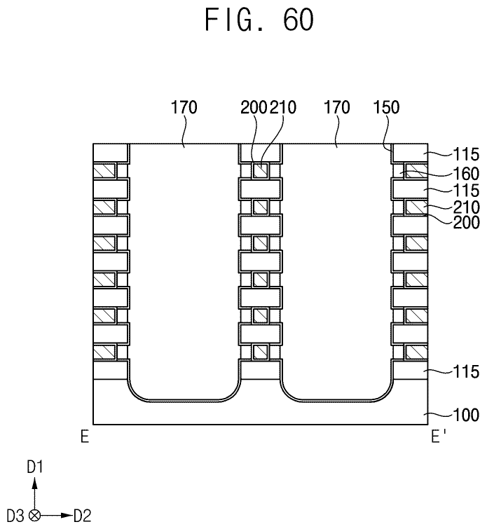

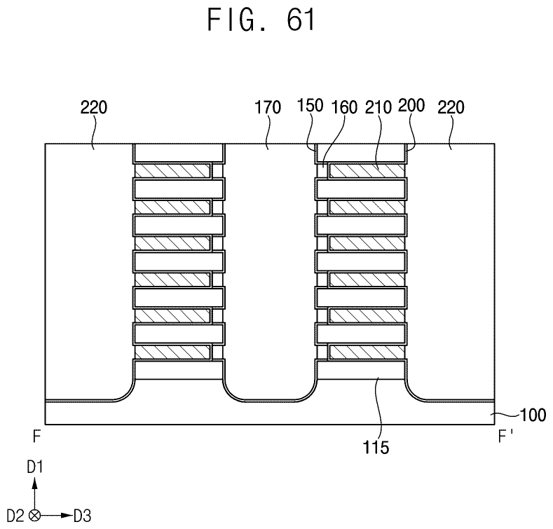

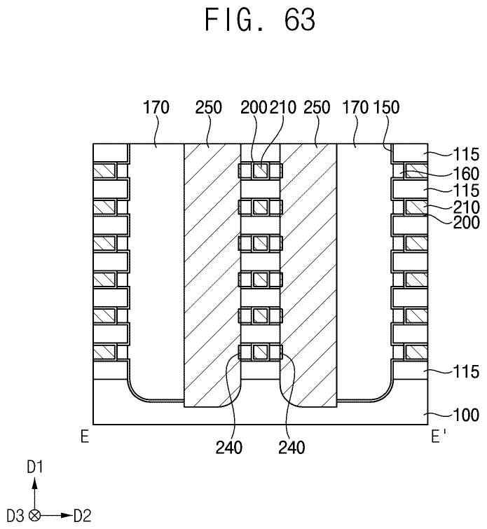

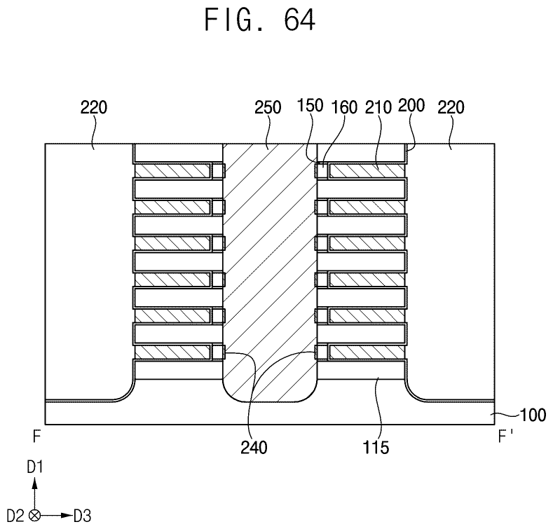

FIGS. 52 to 66 are plan views and cross-sectional views illustrating an example of a method of manufacturing a semiconductor device in accordance with some implementations. Particularly, FIGS. 52, 54, 56, 59, 62, and 65 are the plan views, FIGS. 53, 55, 57, 60, 63, and 66 are cross-sectional views taken along lines E-E′ of corresponding plan views, respectively, and FIGS. 58, 61, and 64 are cross-sectional views taken along lines F-F′ of corresponding plan views, respectively.

In some implementations, the method may include processes substantially the same as or similar to those illustrated with respect to FIGS. 4 to 31 and FIGS. 1 to 3, and repeated explanations thereof are omitted herein.

In FIGS. 52 and 53, processes substantially the same as or similar to those illustrated with respect to FIGS. 4 to 6 may be performed to form the first hole 140 on the first region I of the substrate 100.

A plurality of first holes 140 may be spaced apart from each other in the second direction D2 and the third direction D3 to form a first hole array, which may include a plurality of first hole columns, each of which may include a plurality of first holes 140 disposed in the second direction D2, spaced apart from each other in the third direction D3.

In some implementations, the first hole column may include a plurality of first hole pairs, each of which may include two first holes 140 spaced apart from each other in the second direction D2 by a first distance, spaced apart from each other in the second direction D2 by a second distance greater than the first distance. However, a single first hole 140 may be disposed at each of opposite ends in the second direction D2 of the first hole column. FIGS. 52 and 53 show the first hole 140 at an end of the first hole column and a first hole pair adjacent to the first hole 140.

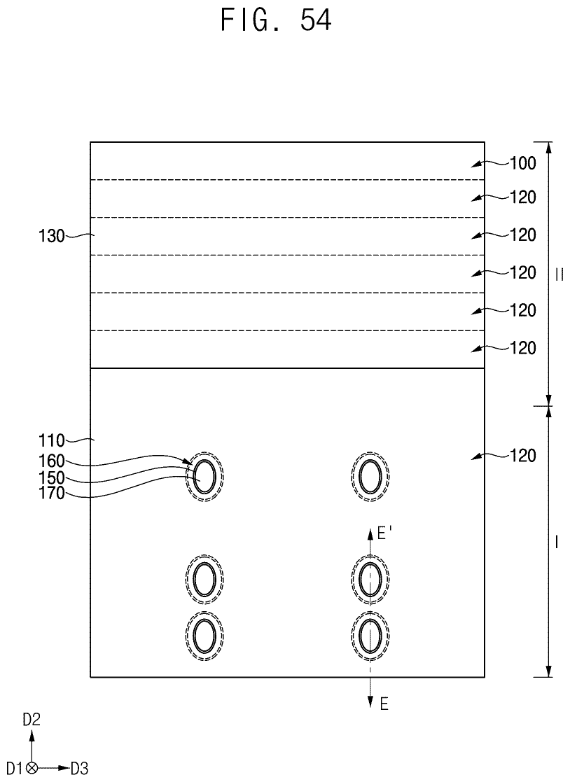

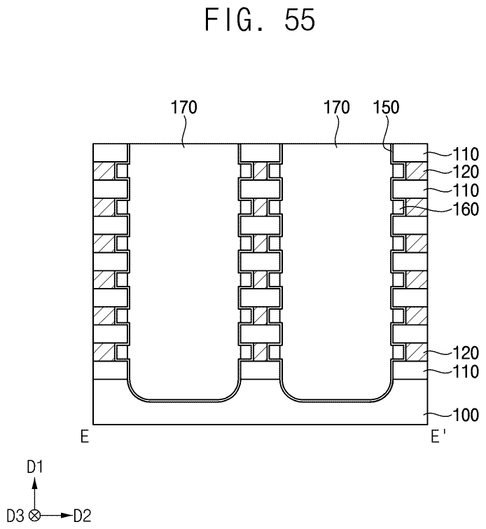

In FIGS. 54 and 55, processes substantially the same as or similar to those illustrated with respect to FIGS. 7 to 10 may be performed to form the second insulation layer 150, the channel 160, and the third insulation pattern 170.

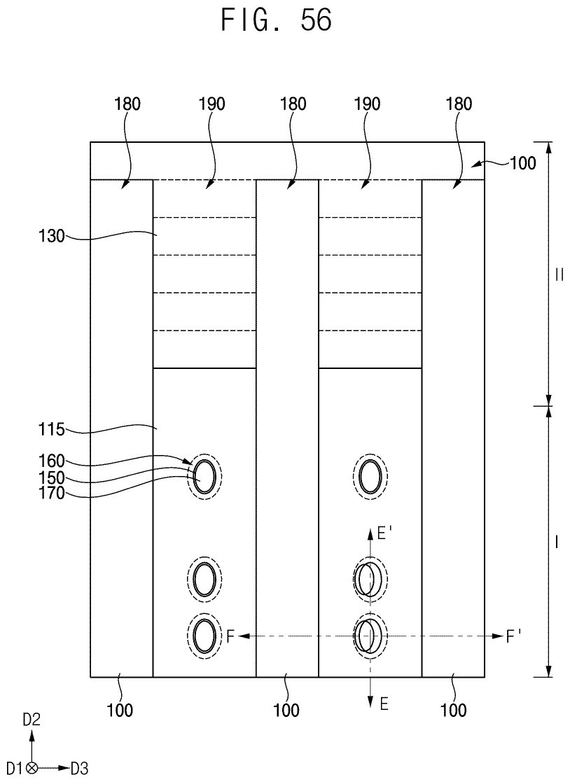

In FIGS. 56 to 58, processes substantially the same as or similar to those illustrated with respect to FIGS. 11 to 13 may be performed to form the first opening 180 and the second recess 190.

In some implementations, each of the first openings 180 may be formed between neighboring ones of the channel columns in the third direction D3, and a single channel column may be formed between neighboring ones of the first openings 180 in the third direction D3. The second recess 190 may be formed by entirely removing the portion of the first sacrificial pattern 125 between the ones of the first openings 180 in the third direction D3, and may expose the sidewall of each of the channels 160 included in the channel column.

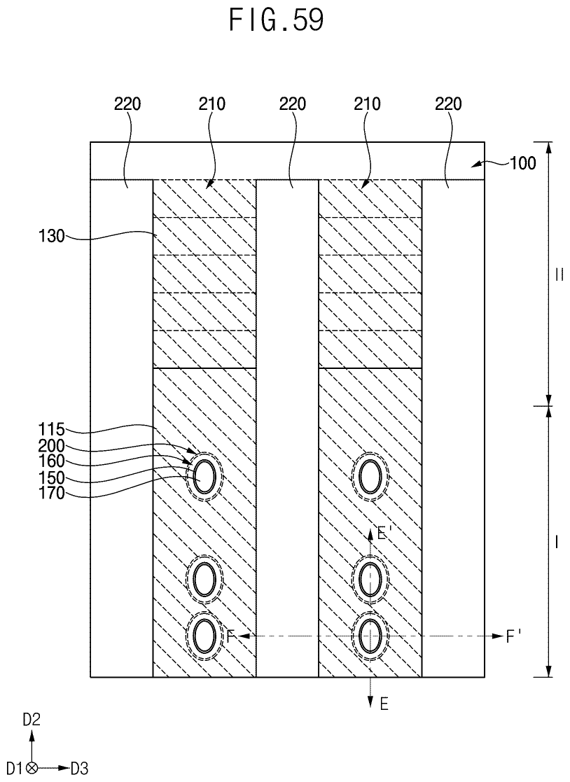

In FIGS. 59 to 61, processes substantially the same as or similar to those illustrated with respect to FIGS. 14 to 18 may be performed to form the first gate insulation layer 200, the first gate electrode 210, and the fourth insulation pattern 220. The first gate insulation layer 200 may surround the sidewall of the channel 160.

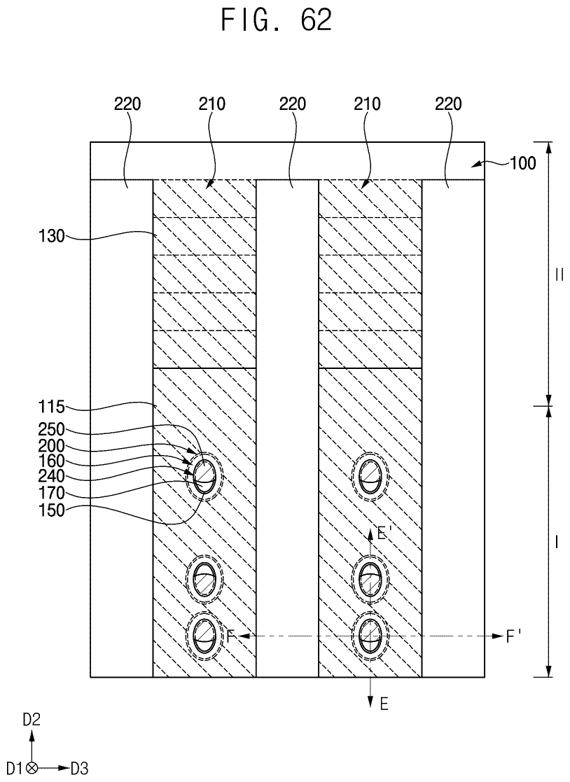

In FIGS. 62 to 64, processes substantially the same as or similar to those illustrated with respect to FIGS. 19 to 24 may be performed to form the first ohmic contact pattern 240 and the bit line 250. However, as shown in FIGS. 33 and 34, in some cases, after entirely removing the third insulation pattern 170, the first ohmic contact pattern 240, and the bit line 250 may be formed.

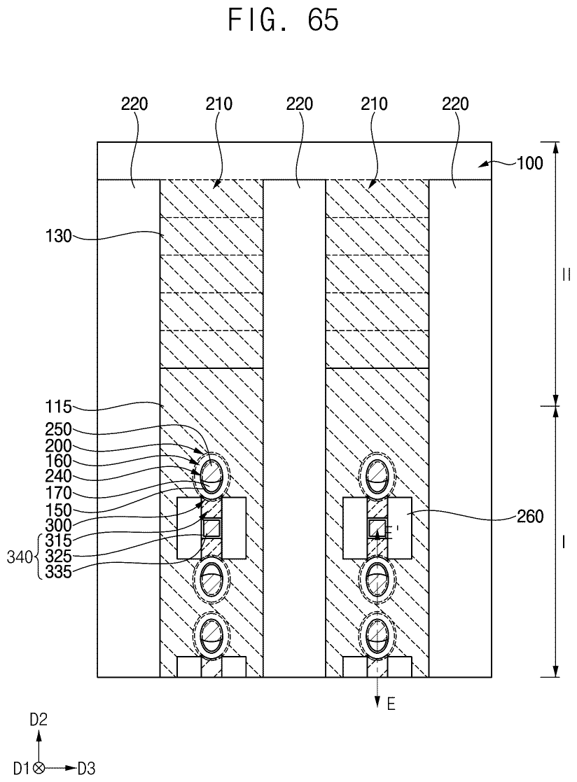

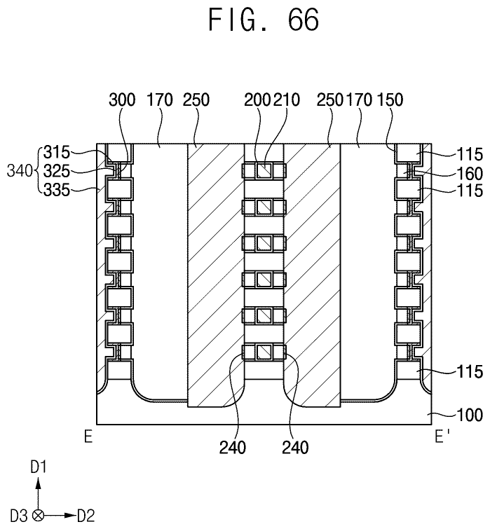

In FIGS. 65 and 66, processes substantially the same as or similar to those illustrated with respect to FIGS. 25 to 31 may be performed to form the fifth insulation pattern 260, the second ohmic contact pattern 300 and the capacitor structure 340.

In FIGS. 49 to 51, processes substantially the same as or similar to those illustrated with respect to FIGS. 1 to 3 may be performed to complete the fabrication of the semiconductor device.

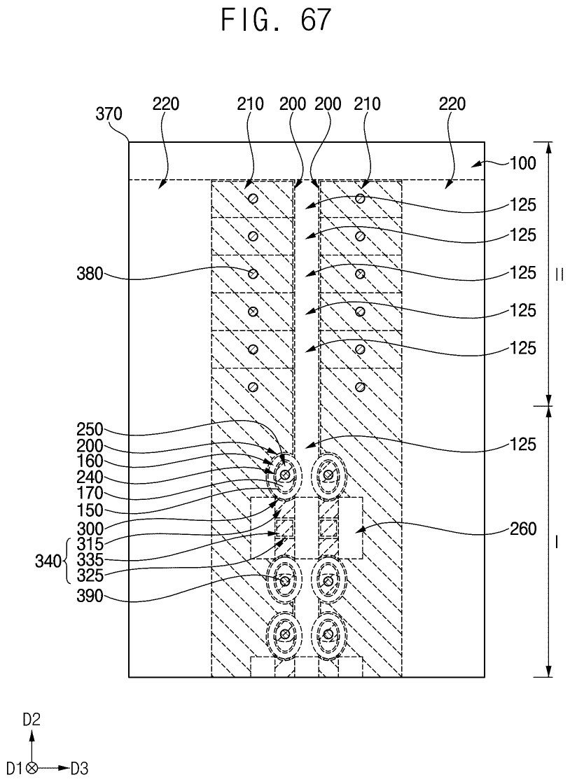

FIG. 67 is a plan view illustrating an example of a semiconductor device in accordance with some implementations. In some implementations, the semiconductor device may be substantially the same as or similar to that of FIGS. 49 to 51, except for some elements, and repeated explanations are omitted herein.

In FIG. 67, unlike that of FIGS. 49 to 51, two first gate electrode structures may be disposed between neighboring ones of the fourth insulation patterns 220 in the third direction D3, and a single bit line column, a single channel column, and a single capacitor structure column may extend through each of the first gate electrode structures.

However, in some implementations, each of the channels 160 included in the channel column may not be entirely surrounded by each of the first gate electrodes 210 included in the first gate electrode structure, and a sidewall in the third direction D3 of each of the channels 160 may be covered by the first sacrificial pattern 125.

In the semiconductor device, the first capacitor electrodes 315, the channels 160, and the bit lines 250 at opposite sides, respectively, in the second direction D2 of the second capacitor electrode 335 may be symmetrical with reference to an imaginary line extending in the third direction D3 and passing the second capacitor electrode 335. Additionally, the capacitor structures 340, the channels 160, and the bit lines 250 at opposite sides, respectively, in the third direction D3 of the fifth insulation pattern 260 may be symmetrical with reference to an imaginary line extending in the second direction D2 and passing the fifth insulation pattern 260.

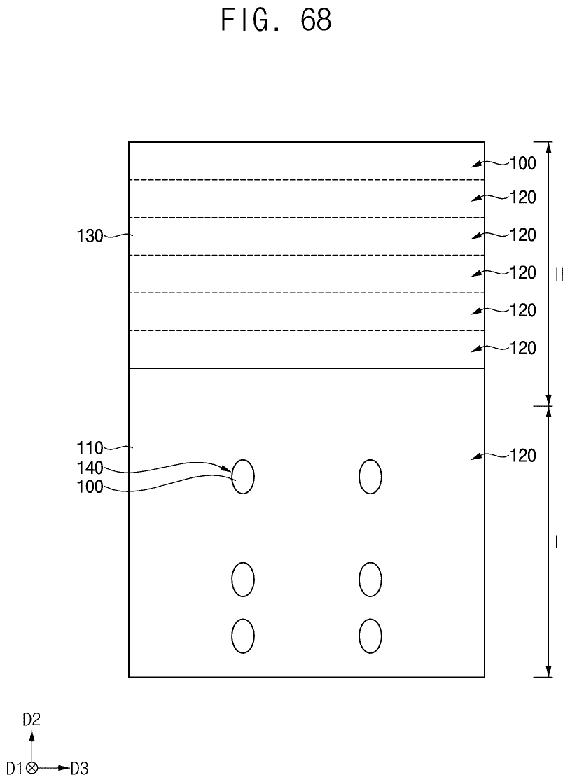

FIGS. 68 to 70 are plan views illustrating an example of a method of manufacturing a semiconductor device in accordance with some implementations. In some implementations, the method may include processes substantially the same as or similar to those illustrated with respect to FIGS. 52 to 66 and FIGS. 49 to 51, and repeated explanations thereof are omitted herein.

In FIG. 68, processes substantially the same as or similar to those illustrated with respect to FIGS. 52 and 53 may be performed to form the first hole 140 on the first region I of the substrate 100.

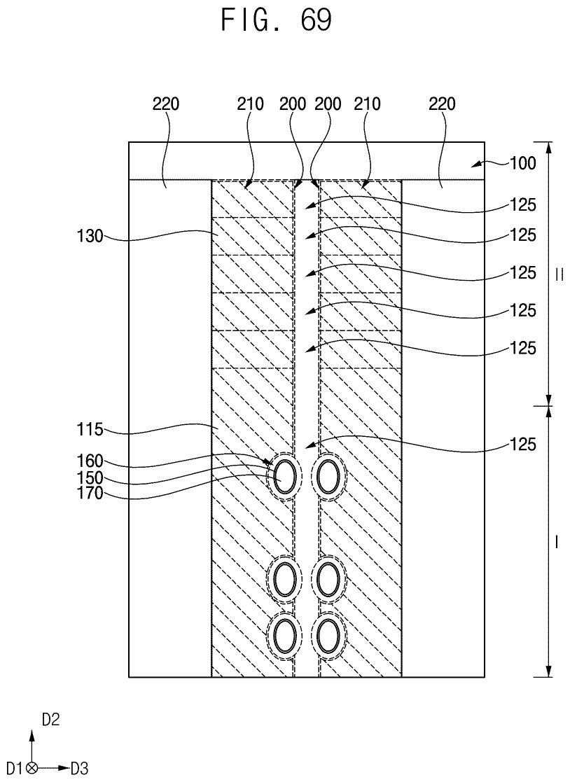

In FIG. 69, processes substantially the same as or similar to those illustrated with respect to FIGS. 54 to 61 may be performed to form the second insulation layer 150, the channel 160, the third insulation pattern 170, the first gate insulation layer 200, the first gate electrode 210, and the fourth insulation pattern 220.

In some implementations, each of the first openings 180 may be formed between neighboring ones of the channel columns in the third direction D3, and two channel columns may be formed between neighboring ones of the first openings 180 in the third direction D3. The second recess 190 may be formed by removing a portion of the first sacrificial pattern 125 between and adjacent to the neighboring ones of the first openings 180 in the third direction D3, and a portion of the first sacrificial pattern 125 at a center between the first openings 180 may not be removed but remain.

The first gate insulation layer 200 may contact a portion of the sidewall of the channel 160, and a remaining portion of the sidewall of the channel 160 may contact the sidewall of the first sacrificial pattern 125.

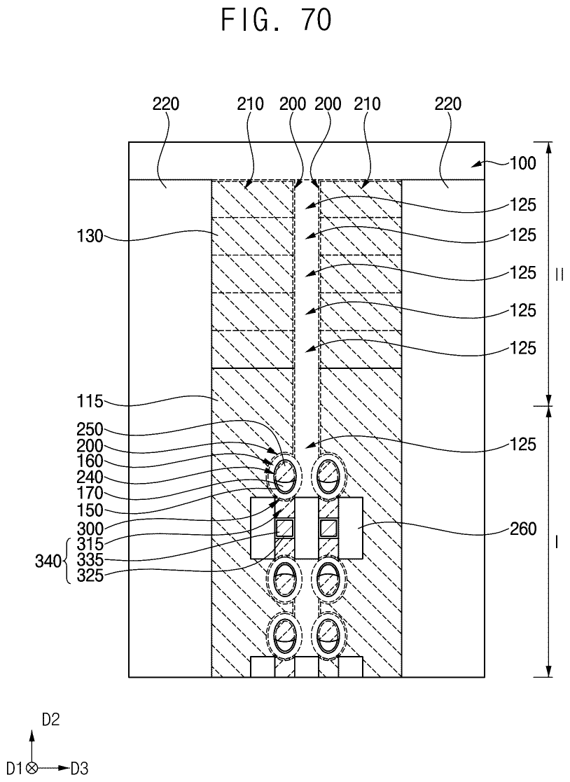

In FIG. 70, processes substantially the same as or similar to those illustrated with respect to FIGS. 62 to 66 may be performed to form the first ohmic contact pattern 240, the bit line 250, the fifth insulation pattern 260, the second ohmic contact pattern 300, and the capacitor structure 340.

In FIG. 67, processes substantially the same as or similar to those illustrated with respect to FIGS. 49 to 51 may be performed to complete the fabrication of the semiconductor device.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor device comprising:
a bit line on a substrate, the bit line extending in a first direction perpendicular to an upper surface of the substrate;
a channel at least partially surrounding a sidewall of the bit line;
a word line on the substrate, at least a portion of the word line overlapping the channel in a horizontal direction parallel to the upper surface of the substrate; and
a capacitor electrically connected to the channel, at least a portion of the capacitor overlapping the channel and the word line in the horizontal direction.

2. The semiconductor device of claim 1, wherein the channel entirely surrounds a sidewall of a portion of the bit line, the portion of the bit line being at a same level as the channel.

3. The semiconductor device of claim 1, further comprising an insulation pattern extending in the first direction and contacting the sidewall of the bit line,
wherein the channel entirely surrounds a sidewall of a portion of the bit line and a portion of the insulation pattern that are disposed at a same level as the channel.

4. The semiconductor device of claim 1, further comprising an ohmic contact pattern between the channel and the sidewall of the bit line.

5. The semiconductor device of claim 1, wherein the word line entirely surrounds a sidewall of the channel.

6. The semiconductor device of claim 1,
wherein the word line extends in a second direction parallel to the upper surface of the substrate, and
wherein the bit line and the capacitor are disposed in a third direction parallel to the upper surface of the substrate and intersecting the second direction.

7. The semiconductor device of claim 1,
wherein the word line extends in a second direction parallel to the upper surface of the substrate, and
wherein the bit line and the capacitor are disposed in the second direction.

8. The semiconductor device of claim 1, wherein the capacitor comprises:
a second capacitor electrode having:
an extension portion extending in the first direction; and
a protrusion portion protruding from a sidewall of the extension portion in the horizontal direction;
a dielectric pattern on a lower surface, an upper surface, and a sidewall of the protrusion portion of the second capacitor electrode, the sidewall of the protrusion portion facing a sidewall of the channel; and
a first capacitor electrode on a lower surface, an upper surface, and a sidewall of the dielectric pattern, the sidewall of the dielectric pattern facing the sidewall of the channel.

9. The semiconductor device of claim 8, further comprising an ohmic contact pattern between the channel and a sidewall of the first capacitor electrode.

10. The semiconductor device of claim 1, further comprising:
a plurality of channels spaced apart from each other in the first direction;
a plurality of word lines spaced apart from each other in the first direction; and
a plurality of capacitors spaced apart from each other in the first direction,
wherein the channel is one of the plurality of channels,
wherein the word line is one of the plurality of word lines, and
wherein the capacitor is one of the plurality of capacitors.

11. The semiconductor device of claim 10,
wherein each of the plurality of word lines extends in a second direction parallel to the upper surface of the substrate; and
wherein lengths in the second direction of the word lines decrease from a lowermost level to an uppermost level in a stepwise manner.

12. The semiconductor device of claim 11, further comprising contact plugs contacting upper surfaces of end portions in the second direction of the word lines, respectively, each of the contact plugs extending in the first direction.

13. A semiconductor device, comprising:
a bit line on a substrate, the bit line extending in a first direction perpendicular to an upper surface of the substrate;
a back gate electrode extending in the first direction on the substrate, the back gate electrode being spaced apart from the bit line in a horizontal direction parallel to the upper surface of the substrate;
a channel at least partially surrounding a sidewall of the back gate electrode, the channel being electrically connected to the bit line;
a word line on the substrate, at least a portion of the word line overlapping the channel in the horizontal direction; and
a capacitor electrically connected to the channel, at least a portion of the capacitor overlapping the channel and the word line in the horizontal direction.

14. The semiconductor device of claim 13, further comprising a gate insulation pattern covering a sidewall and a lower surface of the back gate electrode,
wherein the channel surrounds and contacts a sidewall of a portion of the gate insulation pattern at a same level as the channel.

15. The semiconductor device of claim 13, further comprising an ohmic contact pattern surrounding and contacting a sidewall of the bit line,
wherein the channel contacts the ohmic contact pattern and is electrically connected to the bit line.

16. The semiconductor device of claim 13, further comprising an ohmic contact pattern between the channel and the capacitor.

17. The semiconductor device of claim 13,
wherein the word line extends in a second direction parallel to the upper surface of the substrate, and
wherein the bit line, the back gate electrode, and the capacitor are disposed in a third direction parallel to the upper surface of the substrate, the third direction intersecting the second direction.

18. A semiconductor device, comprising:
bit lines on a substrate, each of the bit lines extending in a first direction perpendicular to an upper surface of the substrate, and the bit lines being spaced apart from each other in a second direction parallel to the upper surface of the substrate;
channels spaced apart from each other in the first direction on a sidewall of each of the bit lines, each of the channels at least partially surrounding the sidewall of each of the bit lines;
word lines spaced apart from each other in the first direction on the substrate, each of the word lines extending in the second direction, and at least a portion of each of the word lines overlapping a corresponding one of the channels in the second direction;
capacitors spaced apart from each other in the first direction, at least a portion of each of the capacitors overlapping a corresponding one of the channels in a third direction parallel to the upper surface of the substrate, the third direction intersecting the second direction; and
contact plugs contacting upper surfaces of corresponding ones, respectively, of the word lines, each of the contact plugs extending in the first direction.

19. The semiconductor device of claim 18, wherein each of the bit lines and a corresponding one of the capacitors are disposed in the third direction.

20. The semiconductor device of claim 18,
wherein the word lines include a plurality of word line structures, each of the plurality of word line structures including ones of the word lines,
wherein the bit lines and the channels at least partially extend through each of the plurality of word line structures,
wherein the semiconductor device further comprises an insulation pattern extending in the second direction between ones of the plurality of word line structures adjacent in the third direction, and
wherein the bit lines at least partially extend through each of the plurality of word line structures and are symmetrical with reference to the insulation pattern, and
wherein the channels at least partially extend through each of the plurality of word line structures and are symmetrical with reference to the insulation pattern.
